(19) United States
(12) Patent Application Publication
(10) Pub. No.: US 2019/0295618 A1
(43) Pub. Date: Sep. 26, 2019

(54) Magnetic Tunnel Junction Devices Including an Annular Free Magnetic Layer and a Planar Reference Magnetic Layer

(71) Applicant: SPIN TRANSFER TECHNOLOGIES, INC., Fremont, CA (US)

(72) Inventor: Satoru ARAKI, San Jose, CA (US)

(21) Appl. No.: 16/122,729

(22) Filed: Sep. 5, 2018

Related U.S. Application Data
(63) Continuation-in-part of application No. 16/059,004, filed on Aug. 8, 2018.
Application No. 16/059,004 is a continuation-in-part of application No. 16/059,009, filed on Aug. 8, 2018.
Application No. 16/059,009 is a continuation-in-part of application No. 16/059,012, filed on Aug. 8, 2018.
Application No. 16/059,012 is a continuation-in-part of application No. 16/059,016, filed on Aug. 8, 2018.
Application No. 16/059,016 is a continuation-in-part of application No. 16/059,018, filed on Aug. 8, 2018.
(60) Provisional application No. 62/647,210, filed on Mar. 23, 2018.

(51) Int. Cl. G11C 11/16; H01L 43/02; H01L 43/08; H01L 43/10; H01L 43/12; H01L 27/22; G11C 7/06

(52) U.S. Cl. CPC G11C 11/161; H01L 43/02; H01L 43/08; H01L 43/10; H01L 43/12; G11C 11/1675; G11C 7/06; G11C 11/1655; G11C 11/1657; G11C 11/1673; H01L 27/226

(57) ABSTRACT

A Magnetic Tunnel Junction (MTJ) can include an annular structure and a planar reference magnetic layer disposed about the annular structure. The annular structure can include an annular non-magnetic layer disposed about an annular conductive layer, an annular free magnetic layer disposed about the annular non-magnetic layer, and an annular tunnel insulator disposed about the annular free magnetic layer. The planar reference magnetic layer can be separated from the free magnetic layer by the annular tunnel barrier layer.

### CROSS-REFERENCE TO RELATED APPLICATIONS

This is a continuation-in-part of U.S. patent application Ser. No. 16/059,004 filed Aug. 8, 2018, U.S. patent application Ser. No. 16/059,009 filed Aug. 8, 2018, U.S. patent application Ser. No. 16/059,012 filed Aug. 8, 2018, U.S. patent application Ser. No. 16/059,016 filed Aug. 8, 2018, and U.S. patent application Ser. No. 16/059,018 filed Aug. 8, 2018; and claims the benefit of U.S. Provisional Patent Application No. 62/647,210 filed Mar. 23, 2018; all of which are incorporated herein in their entirety.

### BACKGROUND OF THE INVENTION

Computing systems have made significant contributions toward the advancement of modern society and are utilized in a number of applications to achieve advantageous results. Numerous devices, such as desktop personal computers (PCs), laptop PCs, tablet PCs, netbooks, smart phones, game consoles, servers, distributed computing systems, Internet of Things (IoT) devices, Artificial Intelligence (AI), and the like have facilitated increased productivity and reduced costs in communicating and analyzing data in most areas of entertainment, education, business, and science. One common aspect of computing systems is the computing device readable memory. Computing devices may include one or more types of memory, such as volatile random-access memory, non-volatile flash memory, and the like.

An emerging non-volatile memory technology is Magnetoresistive Random Access Memory (MRAM). In MRAM devices, data can be stored in the magnetization orientation between ferromagnetic layers of a Magnetic Tunnel Junction (MTJ). Referring to FIG. 1, a MTJ, in accordance with the convention art, is shown. The MTJ can include two magnetic layers 110, 120, and a magnetic tunnel barrier layer 130. One of the magnetic layers 110 can have a fixed magnetization polarization 140, while the polarization of the magnetization of the other magnetic layer 120 can switch between opposite directions. Typically, if the magnetic layers 110, 120 have the same magnetization polarization, the MTJ cell will exhibit a relatively low resistance value corresponding to a ‘1’ bit state; while if the magnetization polarization between the two magnetic layers 110, 120 is antiparallel the MTJ cell will exhibit a relatively high resistance value corresponding to a ‘0’ bit state. Because the data is stored in the magnetic fields, MRAM devices are non-volatile memory devices. The state of a MRAM cell can be read by applying a predetermined current through the cell and measuring the resulting voltage, or by applying a predetermined voltage across the cell and measuring the resulting current. The sensed current or voltage is proportional to the resistance of the cell and can be compared to a reference value to determine the state of the cell.

MRAM devices are characterized by densities similar to Dynamic Random-Access Memory (DRAM), power consumption similar to flash memory, and speed similar to Static Random-Access Memory (SRAM). Although MRAM devices exhibit favorable performance characteristics as compared to other memory technologies, there is a continuing need for improved MRAIVI devices and methods of manufacture thereof.

### SUMMARY OF THE INVENTION

The present technology may best be understood by referring to the following description and accompanying drawings that are used to illustrate embodiments of the present technology directed toward Magnetic Tunnel Junction (MTJ) devices.

In one embodiment, an MTJ structure can include an annular structure and a planar reference magnetic layer disposed about the annular structure. The annular structure can include an annular non-magnetic layer disposed about an annular conductive layer, an annular free magnetic layer disposed about the annular non-magnetic layer, and an annular tunnel insulator disposed about the annular free magnetic layer. The planar reference magnetic layer can be separated from the free magnetic layer by the annular tunnel barrier layer. The MTJ structure can also include a first non-magnetic insulator layer disposed on a first side of the planar reference magnetic layer and about the annular structure. A second non-magnetic insulator layer can be disposed on a second side of the planar reference magnetic layer and about the annular structure. The magnetic field of the planar reference magnetic layer can have a fixed polarization substantially parallel to a major planar orientation of the planar reference magnetic layer. The magnetic field of the annular free magnetic layer can have a polarization substantially parallel to the major planar orientation of the planar reference magnetic layer. The magnetic field of the annular free magnetic layer can switch to being substantially parallel to the magnetic field of the planar reference layer in response to a current flow in a first direction through the conductive annular layer and switch to being substantially anti-parallel to the magnetic field of the planar reference layer in response to a current flow in a second direction through the conductive annular layer.

In another embodiment, a memory device can include an array of MJT cells. Each MTJ cell can include an annular structure and a portion of a planar reference magnetic layer proximate the respective annular structure. Each annular structure can include an annular non-magnetic layer disposed about an annular conductive layer, an annular free magnetic layer disposed about the annular non-magnetic layer, and an annular tunnel insulator disposed about the annular free magnetic layer. The planar reference magnetic layer can be disposed about the plurality of annular structures and separated from the free magnetic layers by the annular tunnel barrier layers.

In yet another embodiment, a memory device can include an array of MTJ cells and a plurality of select elements. The array of MTJ cells can be arranged in cell columns and cell rows in a plurality of cell levels. The MTJ cells in corresponding cell column and cell row positions in the plurality of cell levels can be coupled together in cell strings. Each MTJ cell can include an annular structure including an annular non-magnetic layer disposed about an annular conductive layer, an annular free magnetic layer disposed about the annular non-magnetic layer, and an annular tunnel insulator disposed about the annular free magnetic layer. Each MTJ cell can also include a portion of a respective planar reference magnetic layer disposed about the annular structure, a portion of a respective planar non-magnetic insulator layer disposed on a first side of the planar reference magnetic layer and about the annular structure, and a portion of another respective planar non-magnetic insulator layer disposed on a second side of the planar reference magnetic layer and about the annular structure.

In yet another embodiment, a string of MTJ cells can include one or more annular structures. Each annular structure can include an annular non-magnetic layer disposed about an annular conductive layer, a plurality of annular free magnetic layers disposed about the annular non-magnetic layer, the plurality of annular free magnetic layers separated from each other by corresponding ones of a plurality of non-magnetic separator layers, and an annular tunnel insulator disposed about the annular free magnetic layer. A plurality of planar reference magnetic layers can be disposed about the annular tunnel barrier layer and aligned with corresponding ones of the plurality of portions of the free magnetic layers. Non-magnetic insulator layers can be disposed about the plurality of annular structures and on either side of each planar reference magnetic layer.

In yet another embodiment, the array of MTJ cells can include a plurality of planar reference magnetic layers disposed about respective ones of a plurality of annular structures. Alternatively, the array of MTJ cells can include a plurality of planar reference magnetic layers disposed about a plurality of annular structures. Respective ones of a plurality of bit lines can be disposed on and electrically coupled to respective ones of the plurality of planar reference magnetic layers. In one implementation, the bit lines can be disposed and electrically coupled to the planar reference magnetic layers in a peripheral region of the array of MTJ cells.

In yet another embodiment, fabrication of an MTJ cell can include forming a planar reference magnetic layer on a first planar non-magnetic insulator layer and forming a second planar non-magnetic insulator layer on the planar reference magnetic layer. One or more annular openings can be formed through the second planar non-magnetic insulator layer, the planar reference magnetic layer and the first planar non-magnetic insulator layer. An annular tunnel insulator can be formed on the walls of the one or more annular openings, an annular free magnetic layer can be formed on the annular insulator inside the one or more annular openings, an annular non-magnetic layer can be formed on the annular free magnetic layer inside the one or more annular openings, and an annular conductive core can be formed inside the annular non-magnetic layer in the one or more annular openings.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

Embodiments of the present technology are illustrated by way of example and not by way of limitation, in the figures of the accompanying drawings and in which like reference numerals refer to similar elements and in which:

FIG. 1 shows a Magnetic Tunnel Junction (MTJ), in accordance with the conventional art.

FIG. 2 shows a MTJ, in accordance with aspects of the present technology.

FIG. 3 shows a device including an array of MTJs, in accordance with aspects of the present technology.

FIG. 4 shows a memory cell array, in accordance with aspects of the present technology.

FIG. 5 shows a memory cell array, in accordance with aspects of the present technology.

FIG. 6 shows a memory cell array, in accordance with aspects of the present technology.

FIG. 7 shows a memory cell array, in accordance with aspects of the present technology.

FIG. 8 shows a memory cell array, in accordance with aspects of the present technology.

FIG. 9 shows a memory device, in accordance with aspects of the present technology.

FIG. 10 shows a device including a string of MTJs, in accordance with aspects of the present technology.

FIG. 11 shows a device including a string of MTJs, in accordance with aspects of the present technology.

FIG. 12 shows a device including a string of MTJs, in accordance with aspects of the present technology.

FIG. 13 shows a memory cell array, in accordance with aspect of the present technology.

FIG. 14. shows a memory cell array, in accordance with aspect of the present technology.

FIG. 15 shows a memory cell array, in accordance with aspect of the present technology.

FIG. 16 shows a device including a string of MTJs, in accordance with aspects of the present technology.

FIGS. 17A and 17B show a memory cell array, in accordance with aspect of the present technology.

FIGS. 18A and 18B show a memory cell array, in accordance with aspect of the present technology.

FIGS. 19A-19B show a method of fabricating a MTJ, in accordance with aspects of the present technology.

FIGS. 20A-20F show a method of fabricating a MTJ, in accordance with aspects of the present technology.

FIGS. 21A-21C show a method of fabricating a memory cell array, in accordance with aspects of the present technology.

FIGS. 22A-22C show a method of fabricating a memory cell array, in accordance with aspects of the present technology.

FIGS. 23A-23F show a method of fabricating a memory cell array, in accordance with aspects of the present technology.

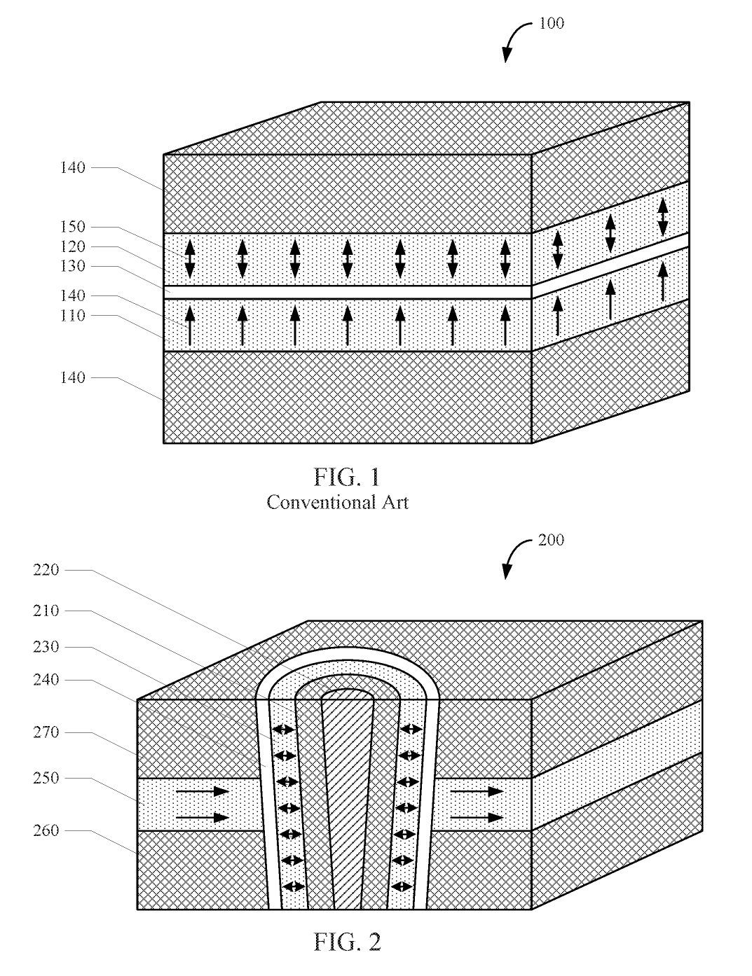

### DETAILED DESCRIPTION OF THE INVENTION

Reference will now be made in detail to the embodiments of the present technology, examples of which are illustrated in the accompanying drawings. While the present technology will be described in conjunction with these embodiments, it will be understood that they are not intended to limit the invention to these embodiments. On the contrary, the invention is intended to cover alternatives, modifications and equivalents, which may be included within the scope of the invention as defined by the appended claims. Furthermore, in the following detailed description of the present technology, numerous specific details are set forth in order to provide a thorough understanding of the present technology. However, it is understood that the present technology may be practiced without these specific details. In other instances, well-known methods, procedures, components, and circuits have not been described in detail as not to unnecessarily obscure aspects of the present technology.

Some embodiments of the present technology which follow are presented in terms of routines, modules, logic blocks, and other symbolic representations of operations on data within one or more electronic devices. The descriptions and representations are the means used by those skilled in the art to most effectively convey the substance of their work to others skilled in the art. A routine, module, logic block and/or the like, is herein, and generally, conceived to be a self-consistent sequence of processes or instructions leading to a desired result. The processes are those including physical manipulations of physical quantities. Usually, though not necessarily, these physical manipulations take the form of electric or magnetic signals capable of being stored, transferred, compared and otherwise manipulated in an electronic device. For reasons of convenience, and with reference to common usage, these signals are referred to as data, bits, values, elements, symbols, characters, terms, numbers, strings, and/or the like with reference to embodiments of the present technology.

It should be borne in mind, however, that all of these terms are to be interpreted as referencing physical manipulations and quantities and are merely convenient labels and are to be interpreted further in view of terms commonly used in the art. Unless specifically stated otherwise as apparent from the following discussion, it is understood that through discussions of the present technology, discussions utilizing the terms such as “receiving,” and/or the like, refer to the actions and processes of an electronic device such as an electronic computing device that manipulates and transforms data. The data is represented as physical (e.g., electronic) quantities within the electronic device's logic circuits, registers, memories and/or the like, and is transformed into other data similarly represented as physical quantities within the electronic device.

In this application, the use of the disjunctive is intended to include the conjunctive. The use of definite or indefinite articles is not intended to indicate cardinality. In particular, a reference to “the” object or “a” object is intended to denote also one of a possible plurality of such objects. It is also to be understood that the phraseology and terminology used herein is for the purpose of description and should not be regarded as limiting.

Referring to FIG. 2, a Magnetic Tunnel Junction (MTJ), in accordance with aspects of the present technology, is shown. The MTJ 200 can include an annular structure 210-240 including an annular non-magnetic layer 210 disposed about an annular conductive layer 220, an annular free magnetic layer 230 disposed about the annular non-magnetic layer 220, and an annular tunnel barrier layer 240 disposed about the annular free magnetic layer 230. The MTJ 200 can also include a planar reference magnetic layer 250 disposed about the annular structure 210-240 and separated from the free magnetic layer 230 by the annular tunnel barrier layer 240.

The MTJ 200 can further include a first set of one or more additional layers 260 disposed about the annular structure 210-240 and on a first side (e.g., bottom side) of the planar reference magnetic layer 250, and a second set of one or more additional layers 270 disposed about the annular structure 210-240 and on a second side (e.g., top) of the planar reference magnetic layer 250. The first set of one or more additional layers 260 can include a first planar non-magnetic insulator layer disposed about the annular structure 210-240 and on a first side of the planar reference magnetic layer 250. The first set of one or more additional layers 260 can include, alternatively or in addition, one or more seed layers, one or more Synthetic Antiferromagnetic (SAF) layers, one or more contacts, a substrate, and/or the like. The second set of one or more additional layers 270 can include a second planar non-magnetic insulator layer disposed about the annular structure 210-240 and on a second side of the planar reference magnetic layer 250. The first and second set of one or more additional layers 260, 270 are not germane to an understanding of aspects of the present technology and therefore will not be discussed in further detail.

In one implementation, the planar reference magnetic layer 250 can include one or more layers of a Cobalt-Iron-Boron (Co—Fe—B) alloy, a Cobalt-Iron (CoFe) alloy, a Cobalt-Iron-Nickle (CoFeNi) alloy, an Iron-Nickle (FeNi) alloy, an Iron-Boron (FeB) alloy, a multilayer of Cobalt-Platinum (CoPt) and Cobalt Paradium (CoPd), a Heusler Alloy selected from Cobalt-Manganese-Silicon (CoMnSi), Cobalt-Manganese-Germanium (CoMnGe), Cobalt-Manganese-Aluminum (CoMnAl), Cobalt-Manganese-Iron-Silicon (CoMnFeSi), Cobalt-Iron-Silicon (CoFeSi), Cobalt-Iron-Aluminum (CoFeA1), Cobalt-Chromium-Iron-Aluminum (CoCrFeAl), Cobalt-Iron-Aluminum-Silicon (CoFeAlSi), or compounds thereof, with a thickness of approximately 1-20 nm, preferably 1 to 10 nm, more preferably 1 to 5 nm. The annular tunnel insulator layer 240 can include one or more layers of a Magnesium Oxide (MgO), Silicon Oxide (SiOx), Aluminum Oxide (AlOx), Titanium Oxide (TiOx) or combination of these oxide materials with a thickness of approximately 0.1-3 nm. The annular free magnetic layer 230 can include one or more layers of a Cobalt-Iron-Boron (Co—Fe—B), Cobalt-Nickle-Iron (CoNiFe), Nickle-Iron (NiFe) alloy or their multilayer combinations with a thickness of approximately 0.5-5 nm. The annular non-magnetic layer 210 can include one or more layers of metal protecting layers that can include one or more elements of a Tantalum (Ta), Chromium (Cr), W, V, Pt, Ru, Pd, Cu, Ag, Rh, or their alloy, with a thickness of approximately 1 to 10 nm. The annular conductive layer 220 can include one or more layers of Copper (Cu), Aluminum (Al), Ruthenium (Ru), and/or one or more alloys thereof with a thickness of approximately 5-20 nm. The first and second additional layers 260, 270 can include one or more layers of MgO, SiOx, AlOx. are alloys thereof with a thickness of the first and second additional layers in the range of 5 to 20 nm, preferably 5 to 10 nm.

In one implementation, the annular structure can be a substantially cylindrical structure with tapered sidewalls, herein referred to as a conical structure. In one implementation, the conical structure can have a taper of approximately 10-45 degrees from a first side of the planar reference magnetic layer 250 to a second side of the planar reference magnetic layer 250. In another expression, the wall angle measured from the normal axis to the horizontal direction of the planar reference magnetic layer 250 can be approximately 10-45 degrees. In one implementation, the annular tunnel insulator 240, the annular free magnetic layer 230, and the annular non-magnetic layer 210 can be concentric regions each bounded by inner and outer respective tapered cylinders having substantially the same axis, disposed about a solid tapered cylindrical region of the annular conductive layer 220.

In an in-plane magnetic field implementation, the magnetic field of the planar reference magnetic layer 250 can have a fixed polarization substantially parallel to a major planar orientation of the planar reference magnetic layer 250. The magnetic field of the annular free magnetic layer 230 can have a polarization that is also substantially parallel to the major planar orientation of the planar reference magnetic layer 250 and selectively switchable between being substantially parallel and substantially antiparallel to the magnetic field of the planar reference magnetic layer 250. In one implementation, the magnetic field of the annular free magnetic layer 230 can be configured to switch to being substantially parallel to the magnetic field of the planar reference magnetic layer 250 in response to a current flow in a first direction through the conductive annular layer 220 and to switch to being substantially anti-parallel to the magnetic field of the planar reference magnetic layer 250 in response to a current flow in a second direction through the conductive annular layer 220. More generally, the polarization direction, either parallel or anti-parallel, can be changed by a corresponding change in the current direction. Therefore, regardless of the definition of the current flowing direction, the polarization of the annular free magnetic layer 230 can switch to the other polarization orientation by switching the current direction.

In a perpendicular magnetic field implementation, the magnetic field of the planar reference magnetic layer can have a fixed polarization substantially perpendicular to a major planar orientation of the planar reference magnetic layer. The magnetic field of the annular free magnetic layer can have a polarization substantially perpendicular to the major planar orientation of the planar reference magnetic layer and selectively switchable between being substantially parallel and substantially antiparallel to the magnetic field of the planar reference magnetic layer.

The in-plane magnetic field implementation can also be referred to as in-plane magnetic anisotropy, and the perpendicular magnetic field implementation can be referred to as perpendicular magnetic anisotropy. The in-plane magnetic field implementation can advantageously result in a 20-50% reduction in the write voltage potential, which can increase the endurance of the MTJ cell 200 by 2-6 orders of decades and or increase the writing speed by 2-10 time faster as compared to the perpendicular magnetic field implementation.

Referring now to FIG. 3, a device including an array of Magnetic Tunnel Junctions (MTJs), in accordance with aspects of the present technology, is shown. The device can include a plurality of annular structures 310-360 and a planar reference magnetic layer 370. The plurality of annular structures 310-360 can each include an annular non-magnetic layer 210 disposed about an annular conductive layer 220, an annular free magnetic layer 230 disposed about the annular non-magnetic layer 220, and an annular tunnel insulator 240 disposed about the annular free magnetic layer 230, as described above in more detail with reference to FIG. 2. The planar reference magnetic layer 370 can be disposed about the plurality of annular structures 310-360 and separated from the free magnetic layers 230 by the annular tunnel barrier layers 240. The device can also include a first set of one or more additional layers 380 disposed about the plurality of annular structures 310-360 and on a first side of the planar reference magnetic layer 370. The device can also include a second set of one or more additional layers 390 disposed about the plurality of annular structures 310-360 and on a second side of the planar reference magnetic layer 370.

In aspects, each annular structure 310-360 and the corresponding portion of the planar reference magnetic layer 370 proximate the respective annular structure 310-360 can form a MTJ cell. In an in-plane magnetic field implementation, the magnetic field of the planar reference magnetic layer 370 can have a fixed polarization substantially parallel to a major planar orientation of the planar reference magnetic layer 370. The magnetic field of the annular free magnetic layer 230 can have a polarization substantially parallel to the major planar orientation of the planar reference magnetic layer 370 and selectively switchable between being substantially parallel and substantially antiparallel to the magnetic field of the planar reference magnetic layer 370. In one implementation, the magnetic field of the annular free magnetic layer 230 can be configured to switch to being substantially parallel to the magnetic field of the planar reference magnetic layer 370 in response to a current flow in a first direction through a respective conductive annular layer 220 and to switch to being substantially anti-parallel to the magnetic field of the planar reference magnetic layer 370 in response to a current flow in a second direction through the respective conductive annular layer 220.

In a perpendicular magnetic field implementation, the magnetic field of the planar reference magnetic layer 370 can have a fixed polarization substantially perpendicular to a major planar orientation of the planar reference magnetic layer 370. The magnetic field of the annular free magnetic layers 230 can have a polarization substantially perpendicular to the major planar orientation of the planar reference magnetic layer 370 and selectively switchable between being substantially parallel and substantially antiparallel to the magnetic field of the planar reference magnetic layer 370.

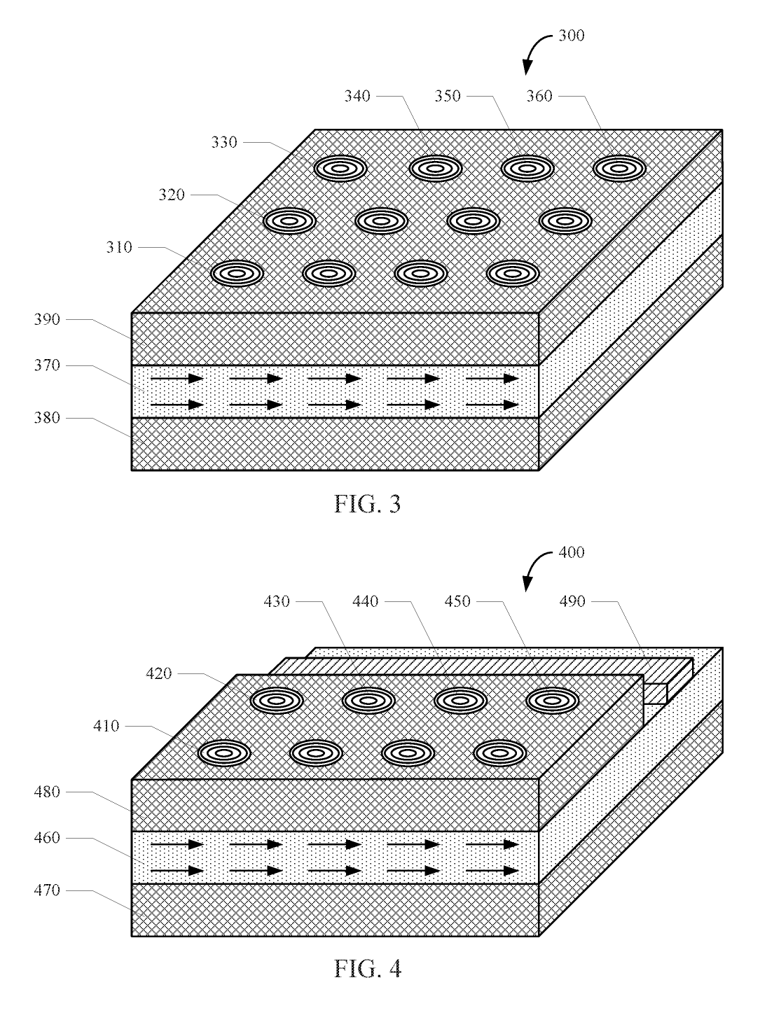

Referring now to FIG. 4, a memory cell array, in accordance with aspects of the present technology, is shown. The memory cell array can include a plurality of MTJ cells. Each MTJ cell can include an annular structure 410-450 and a corresponding portion of a planar reference magnetic layer 460. The annular structures 410-450 can each include an annular non-magnetic layer 210 disposed about an annular conductive layer 220, an annular free magnetic layer 230 disposed about the annular non-magnetic layer 220, and an annular tunnel insulator 240 disposed about the annular free magnetic layer 230, as described above in more detail with reference to FIG. 2. The planar reference magnetic layer 460 can be disposed about the plurality of annular structures 410-450 and separated from the free magnetic layers 230 by the annular tunnel barrier layers 240. The memory cell array can also include a first set of one or more additional layers 470 disposed about the plurality of annular structures 410-450 and on a first side of the planar reference magnetic layer 460. The memory cell array can also include a second set of one or more additional layers 480 disposed about the plurality of annular structures 410-450 and on a second side of the planar reference magnetic layer 460.

In an in-plane magnetic field implementation, the magnetic field of the planar reference magnetic layer 460 can have a fixed polarization substantially parallel to a major planar orientation of the planar reference magnetic layer 460. The magnetic field of the annular free magnetic layer 230 can have a polarization that is also substantially parallel to the major planar orientation of the planar reference magnetic layer 460 and selectively switchable between being substantially parallel and substantially antiparallel to the magnetic field of the planar reference magnetic layer 460. In a perpendicular magnetic field implementation, the magnetic field of the planar reference magnetic layer 460 can have a fixed polarization substantially perpendicular to a major planar orientation of the planar reference magnetic layer 460. The magnetic field of the annular free magnetic layer 230 can have a polarization substantially perpendicular to the major planar orientation of the planar reference magnetic layer 460 and selectively switchable between being substantially parallel and substantially antiparallel to the magnetic field of the planar reference magnetic layer 460. In one implementation, the magnetic field of the annular free magnetic layer 230 can be configured to switch to being substantially parallel to the magnetic field of the planar reference layer magnetic 460 in response to a current flow in a first direction through the conductive annular layer 220 and to switch to being substantially anti-parallel to the magnetic field of the planar reference magnetic layer 460 in response to a current flow in a second direction through the conductive annular layer 220. Typically, if the planar reference magnetic layer 460 and the annular free magnetic layer 230 have the same magnetization polarization, the MTJ cell will exhibit a relatively low resistance value corresponding to a ‘1’ bit state; while if the magnetization polarization between the two magnetic layers is antiparallel the MTJ cell will exhibit a relatively high resistance value corresponding to a ‘0’ bit state. Accordingly, the MTJ cells can also be schematically represented as resistive cell elements.

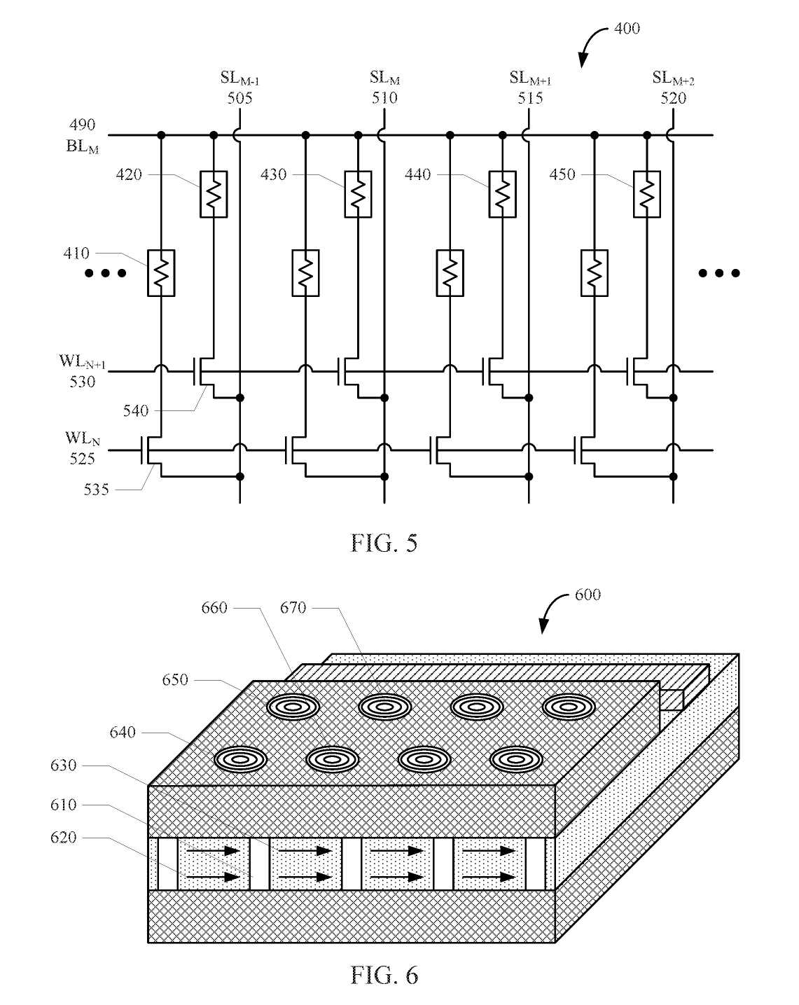

The memory cell array can also include a plurality of bit lines 490, a plurality of source lines, a plurality of word lines, and a plurality of select transistors. The plurality of bit lines 490 can be coupled to the planar reference magnetic layer 460. The annular conductive layer 220 of each annular structure 410-450 can comprise a portion of a respective plurality of source line. The memory cell array 400 will be further explained with reference to FIG. 5, which illustrates a schematic representation of the memory cell array.

Referring now to FIG. 5, the memory cell array 500 can include a plurality of MTJ cells 410-450, a plurality of bit lines 490, a plurality of source lines 505-520, a plurality of word lines 525, 530, and a plurality of select transistor 535, 540. The MTJ cells arranged along columns 410, 420 can be coupled by a corresponding select transistor 535, 540 to a respective source line 505. The gate of the select transistors 535, 540 can be coupled to a respective word line 525, 530. In one implementation, a logic ‘0’ state can be written to a given memory cell 410 by biasing the respective bit line 490 at a bit line write potential (e.g., V_{BLW}), biasing the respective source line 505 at a ground potential, and driving the respective word line 525 at a word line write potential (e.g., V_{WLW}=V_{Hi}). The word lines 530 for the cells that are not being written to can be biased at a ground potential. In addition, the other source lines 510-520 can be biased at a high potential or held in a high impedance state. The high potential can be equal to the bit line write potential or some portion thereof. A logic ‘1’ state can be written to the given memory cell 410 by biasing the respective bit line 490 at a ground potential, biasing the respective source line 505 at a source line write potential (e.g., V_{SLW}), and driving the respective word line 525 at the word line write potential (e.g., V_{WLW}=V_{Hi}). The word lines 530 for the cells that are not being written to can be biased at ground potential. In addition, the other source lines 510-520 can be biased at a low potential or held in a high impedance state. The state of the given memory cell 410 can be read by biasing the respective bit line 490 at a bit line read potential (e.g., V_{BLR}), biasing the respective source line 505 at a ground potential, driving the respective word line 525 at a word line read potential (V_{WLR}=V_{Hi}), and sensing the resulting current on the respective source line 505. The word lines 530 for the cells that are not being read can be biased at a ground potential. In addition, the other source lines 510-520 can be biased at a high potential or held in a high impedance state. The high potential can be equal to the bit line read potential or some portion thereof.

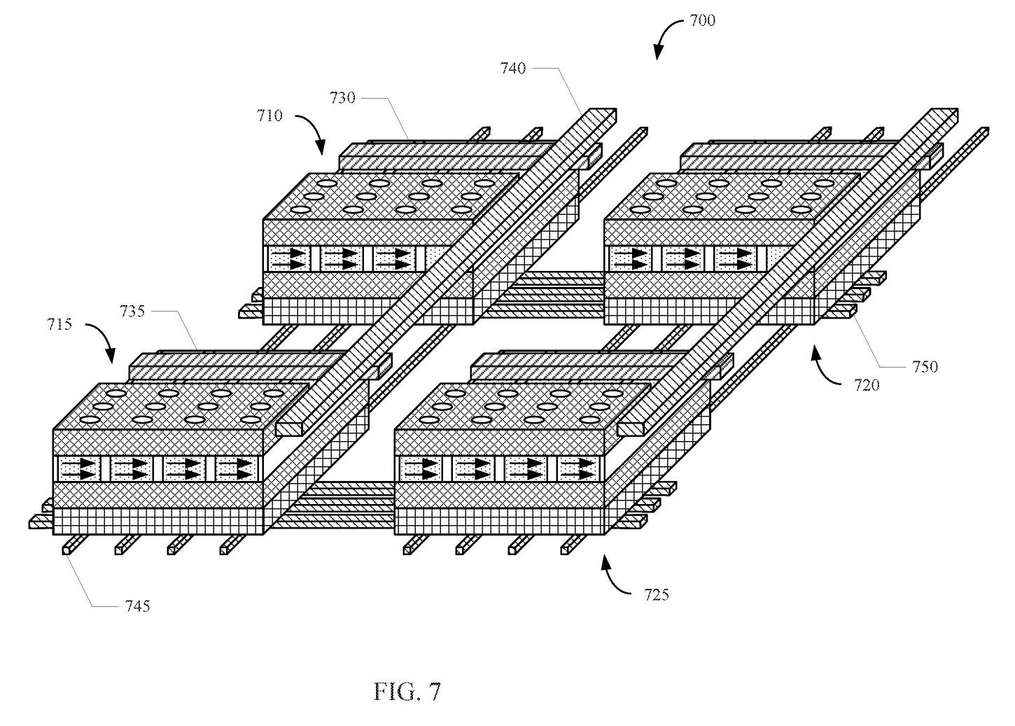

Referring now to FIG. 6, a memory cell array, in accordance with aspects of the present technology, is shown. The memory cell array can include a plurality of MTJ cells as described above in more detail with respect to FIG. 4. The memory cell array can further include a plurality of insulator regions 610 disposed between portions 620, 630 of the planar reference magnetic layer along columns of the annular structures 640, 650 and 660, 670.

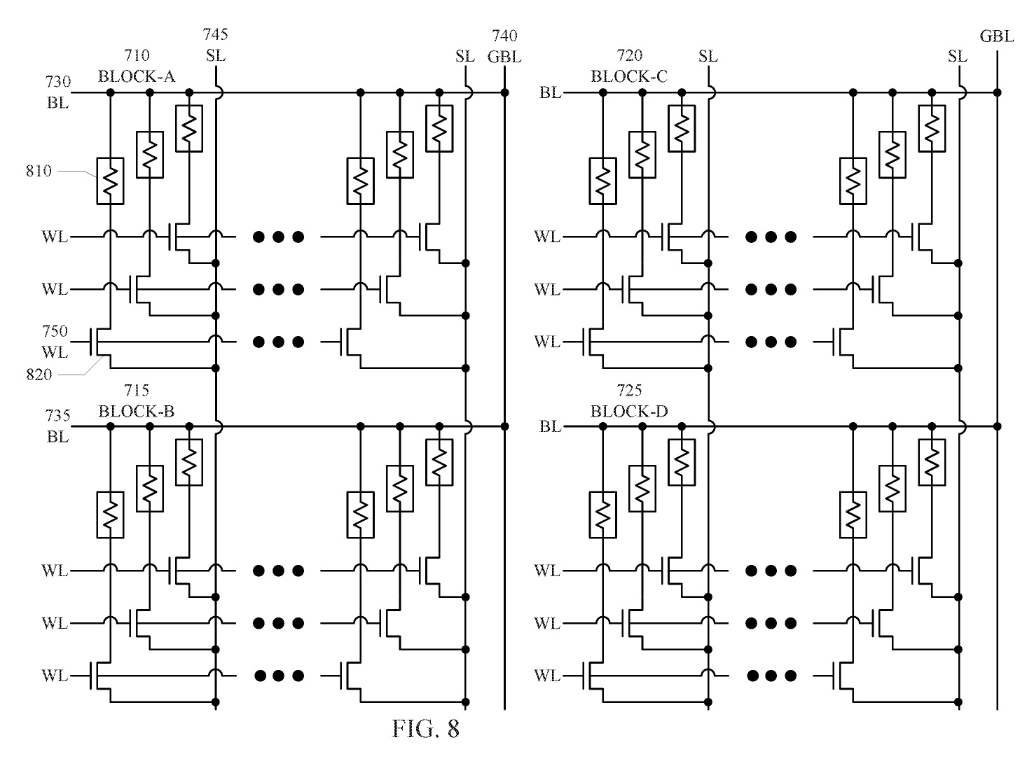

Referring now to FIG. 7, a memory device, in accordance with aspects of the present technology, is shown. The memory device 700 can include a plurality of memory cell array blocks 705-720. Each memory cell array block 705-720 can include a plurality of MTJ cells as described above in more tail with respect to FIGS. 4 and 6. Two or more bit lines 730, 735 of the memory cell array blocks 710, 715 arranged in respective columns can be coupled together by a corresponding global bit line 740. In addition, the source lines 745 of the memory cell array blocks 710, 715 arranged in respective columns can be coupled together. Likewise, the word lines 750 of the memory cell array blocks 715, 725 arranged in respective rows can be coupled together. The memory device 700 will be further explained with reference to FIG. 8, which illustrates a schematic representation of the memory device.

Referring now to FIG. 8, the memory device 700 can include a plurality of memory cell array blocks 705-720. Each memory cell array block can include a plurality of MTJ cells 810, a plurality of bit lines 730, a plurality of source lines 745, a plurality of word lines 750, and a plurality of select transistor 820. The MTJ cells arranged along columns 810 420 can be coupled by a corresponding select transistor 820 to a respective source line 745. The gate of the select transistors can be coupled to a respective word line 750. Two or more bit lines 730, 735 of the memory cell array blocks 710, 715 arranged in respective columns can be coupled together by a corresponding global bit line 740. In addition, the source lines 745 of the memory cell array blocks 710, 715 arranged in respective columns can be coupled together. Likewise, the word lines 750 of the memory cell array blocks 715, 725 arranged in respective rows can be coupled together.

In one implementation, logic ‘0’ and ‘1’ states can be written to a given memory cell 810 by biasing the global bit line 740 which also biases the respective bit line 730 at a bit line write potential (e.g., V_{BLW}), biasing the respective source line 745 at a ground potential, and driving the respective word line 525 at a word line write potential (e.g., V_{WLW}=V_{Hi}). The word lines for the cells that are not being written to can be biased at a ground potential. In addition, the other source lines can be biased at a high potential or held in a high impedance state. The high potential can be equal to the bit line write potential or some portion thereof. A logic ‘1’ state can be written to the given memory cell 810 by biasing the global bit line 740 which also biases the respective bit line 730 at a ground potential, biasing the respective source line 745 at a source line write potential (e.g., V_{SLW}), and driving the respective word line 750 at the word line write potential (e.g., V_{WLW}=V_{Hi}). The word lines for the cells that are not being written to can be biased at ground potential. In addition, the other source lines can be biased at a low potential or held in a high impedance state. The state of the given memory cell 810 can be read by biasing the global bit line 740 which also biases the respective bit line 730 at a bit line read potential (e.g., V_{BLR}), biasing the respective source line 745 at a ground potential, driving the respective word line 750 at a word line read potential (V_{WLR}=V_{Hi}), and sensing the resulting current on the respective source line 745. The word lines for the cells that are not being read can be biased at a ground potential. In addition, the other source lines can be biased at a high potential or held in a high impedance state. The high potential can be equal to the bit line read potential or some portion thereof.

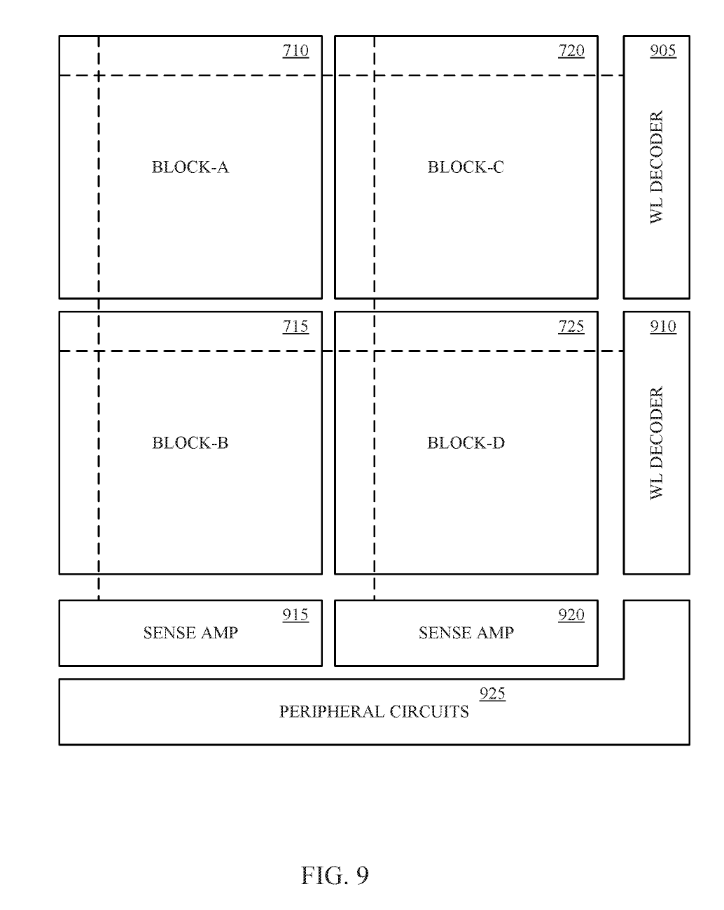

Referring now to FIG. 9, a memory device, in accordance with aspects of the present technology, is shown. In one implementation, the memory device can be a Magnetoresistive Random Access Memory (MRAM). The memory device 900 can include a plurality of memory cell array blocks 710-725, one or more word line decoders 905, 910, one or more sense amplifier circuits 915, 920, and peripheral circuits 925. The memory device 900 can include other well-known circuits that are not necessary for an understanding of the present technology and therefore are not discussed herein.

Each memory cell array block 710-725 can include can include a plurality of MTJ cells 810, a plurality of bit lines 730, a plurality of source lines 745, a plurality of word lines 750, and a plurality of select transistor 820 as described in more detail above with reference to FIGS. 7 and 8. The peripheral circuits 925, the word line decoders 905, 910 and sense amplifier circuits 915, 920 can map a given memory address to a particular row of MTJ memory cells in a particular memory cell array block 710-725. The output of the word line drivers 905, 910 can drive the word lines to select a given word line of the array. The sense amplifier circuits 915, 920 utilize the source lines and bit lines of the array to read from and write to memory cells of a selected word line in a selected memory cell array block 710-725.

In one aspect, the peripheral circuits 925 and the word line decoders 905, 910 can be configured to apply appropriate write voltages to bit lines, source lines and word lines to write data to cells in a selected word. The magnetic polarity, and corresponding logic state, of the free layer of the MTJ cell can be changed to one of two states depending upon the direction of current flowing through the MTJ cell. For read operations, the peripheral circuits 925, the word line decoders 905, 910 and sense amplifier circuits 915, 920 can be configured to apply appropriate read voltages to the bit lines, sources lines and word lines to cause a current to flow in the source lines that can be sensed by the sense amplifier circuits 915, 920 to read data from cells in a selected word.

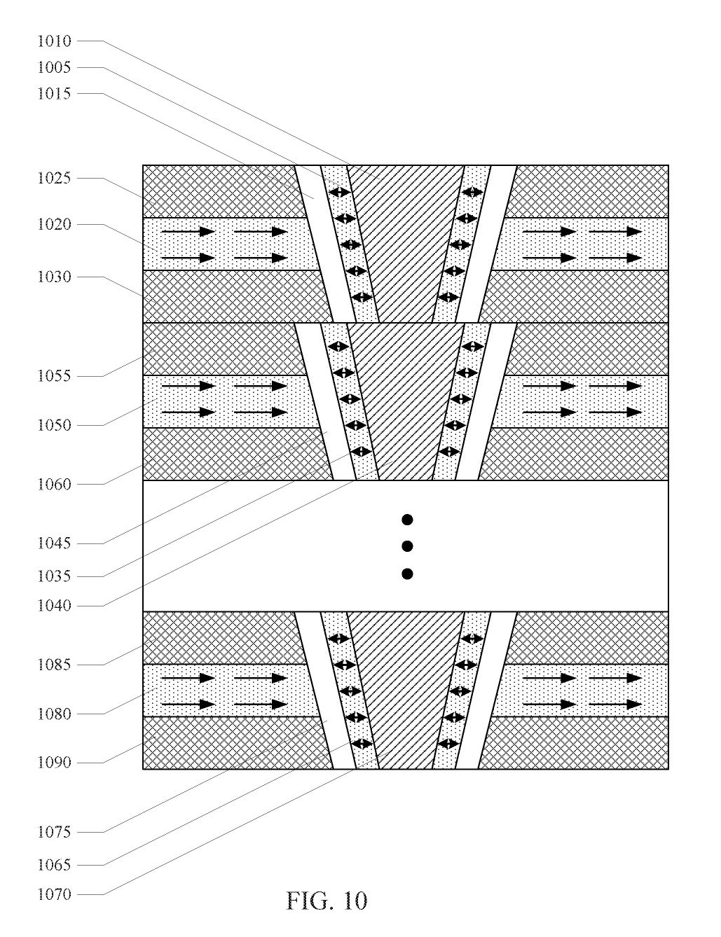

Referring now to FIG. 10 a device including a string of MTJs, in accordance with aspects of the present technology, is shown. The device can include a first annular structure 1005-1015 including an annular free magnetic layer 1005 disposed about an annular conductive layer 1010, and an annular tunnel insulator 1015 disposed about the annular free magnetic layer 1005. The annular structure can optionally include an annular non-magnetic layer (not shown) disposed between the annular conductive layer 1010 and the annular free magnetic layer 1005. A first planar reference magnetic layer 1020 can be disposed about the first annular structure 1005-1015 and separated from the free magnetic layer 1005 of the first annular structure by the annular tunnel barrier layer 1015 of the first annular structure. A first non-magnetic insulator layer 1025 can be disposed about the first annular structure and on a first side of the first planar reference magnetic layer 1020. A second non-magnetic insulator layer 1030 can be disposed about the first annular structure and on a second side of the first planar reference magnetic layer 1020.

The device can further include a second annular structure 1035-1045. The second annular structure 1035-1045 can be axially aligned with the first annular structure 1005-1015. The second annular structure can include an annular free magnetic layer 1035 disposed about an annular conductive layer 1040, and an annular tunnel insulator 1045 disposed about the annular free magnetic layer 1035. The second annular structure can optionally include an annular non-magnetic layer (not shown) disposed between the annular conductive layer 1040 and the annular free magnetic layer 1035. A second planar reference magnetic layer 1050 can be disposed about the second annular structure 1035-1045 and separated from the free magnetic layer 1035 of the second annular structure by the annular tunnel barrier layer 1045 of the second annular structure. A third non-magnetic insulator layer 1055 can be disposed about the second annular structure, and between the second non-magnetic insulator layer 1030 and a first side of the second planar reference magnetic layer 1050. A fourth non-magnetic insulator layer 1060 can be disposed about the second annular structure and on a second side of the second planar reference magnetic layer 1050.

Each annular structure and the portions of the planar reference magnetic layer and the non-magnetic insulator layers proximate the respective annular structure can comprise a MTJ cell. The device can include any number of MTJ cells coupled together in a string. For example, a N^{th} level string of MTJ cells can include a N^{th} annular structure 1065-1075 The N^{th} annular structure 1065-1075 can be axially aligned with the first and second annular structures 1005-1015, 1035-1045. The N^{th} annular structure can include an annular free magnetic layer 1065 disposed about an annular conductive layer 1070, and an annular tunnel insulator 1075 disposed about the annular free magnetic layer 1065. The N^{th} annular structure can optionally include an annular non-magnetic layer (not shown) disposed between the annular conductive layer 1070 and the annular free magnetic layer 1065. A N^{th} planar reference magnetic layer 1080 can be disposed about the N^{th} annular structure 1065-1075 and separated from the free magnetic layer 1065 of the N^{th} annular structure by the annular tunnel barrier layer 1075 of the N^{th} annular structure. A (N-1)^{th} non-magnetic insulator layer 1085 can be disposed about the N^{th} annular structure, and between the non-magnetic insulator layer of an adjacent cell and a first side of the second planar reference magnetic layer 1080. A N^{th} non-magnetic insulator layer 1090 can be disposed about the N^{th} annular structure and on a second side of the N^{th} planar reference magnetic layer 1080.

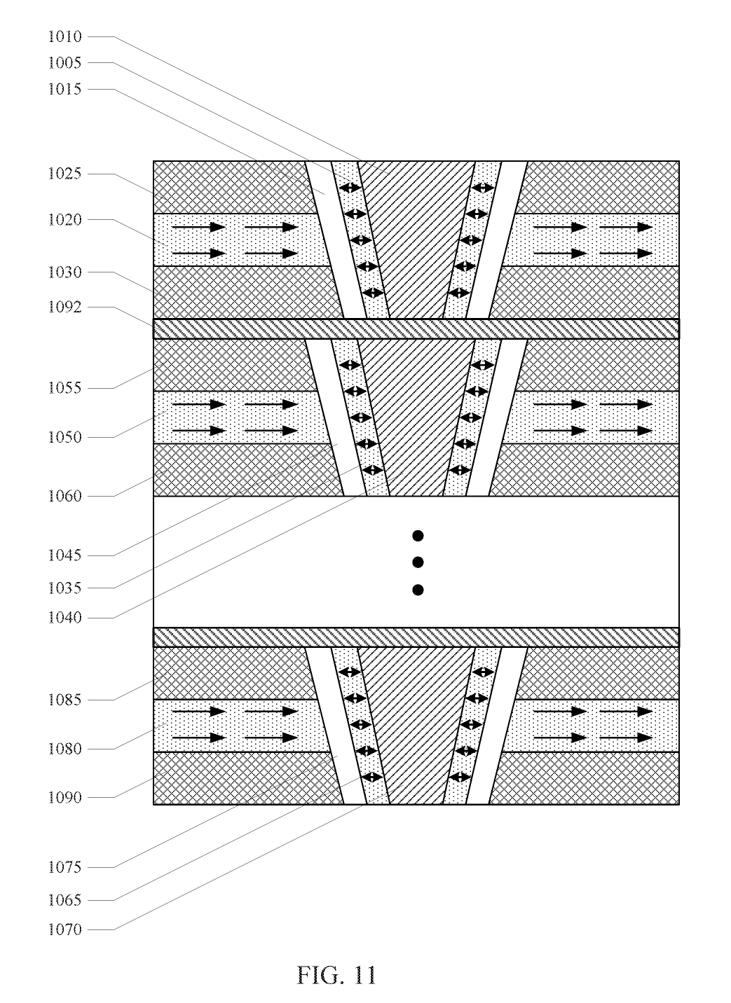

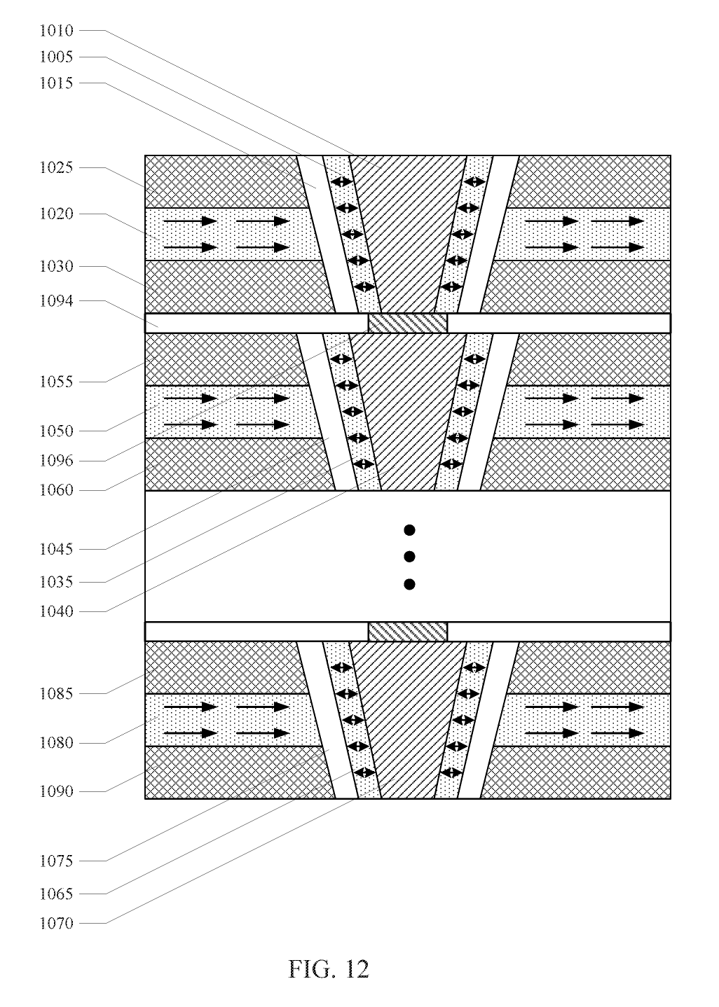

The device can optionally include a non-magnetic metal layer 1092 disposed between adjacent MTJ cells, as illustrated in FIG. 11. For example, a non-magnetic metal layer 1092 can be disposed between the second non-magnetic insulator layer 1030 and the third non-magnetic insulator layer 1055 and between the first annular structure 1005-1015 and the second annular structure 1035-1045. Alternatively, the device can optionally include a non-magnetic insulator layer 1094 and a non-magnetic metal plug 1096 disposed between adjacent MTJ cells, as illustrated in FIG. 12. For example, an additional non-magnetic insulator layer 1094 can be disposed between the second non-magnetic insulator layer 1030 and the third non-magnetic insulator layer 1055 and one or more portions of the first and second annular structures 1005-1015, 1035-1045. A non-magnetic metal plug 1096 can be disposed between respective ones of the annular conductive layer 1010 of the first annular structure 1005-1015 and the annular conductive layer 1040 of the second annular structure 1035-1045.

In one implementation, the annual structures 1005-1015, 1035-1045, 1065-1075 can be substantially cylindrical structures with tapered sidewalls, herein referred to as conical structures. In one implementation, the conical structures can have a taper of approximately 10-45 degrees from a first side of the planar reference magnetic layers 1020, 1050, 1080 to a second side of the planar reference magnetic layers 1020, 1050, 1080. In another expression, the wall angle measured from the normal axis to the horizontal direction of the planar reference magnetic layers 1020, 1050, 1080 can be approximately 10-45 degrees. In one implementation, the annular tunnel insulators 1015, 1045, 1075, and the annular free magnetic layer 1005, 1035, 1065 can be concentric regions each bounded by inner and outer respective tapered cylinders having substantially the same axis, disposed about a solid tapered cylindrical region of the annular conductive layers 1010, 1040, 1070. In one implementation, the taper angle of the sidewalls can provide for separating the annular free magnetic layers 1005, 1035, 1065 of the annual structures 1005-1015, 1035-1045, 1065-1075 from each other, while the annular conductive layers 1010, 1040, 1070 are coupled together along the string.

In an in-plane magnetic field implementation, the magnetic field of the planar reference magnetic layers 1020, 1050, 1080 can have a fixed polarization substantially parallel to a major planar orientation of the planar reference magnetic layers 1020, 1050, 1080. The magnetic field of the annular free magnetic layers 1005, 1035, 1065 can have a polarization substantially parallel to the major planar orientation of the planar reference magnetic layers 1020, 1050, 1080 and selectively switchable between being substantially parallel and substantially antiparallel to the magnetic field of the planar reference magnetic layers 1020, 1050, 1080. In a perpendicular magnetic field implementation, the magnetic field of the planar reference magnetic layers 1020, 1050, 1080 can have a fixed polarization substantially perpendicular to a major planar orientation of the planar reference magnetic layers 1020, 1050, 1080. The magnetic field of the annular free magnetic layers 1005, 1035, 1065 can have a polarization substantially perpendicular to the major planar orientation of the planar reference magnetic layers 1020, 1050, 1080 and selectively switchable between being substantially parallel and substantially antiparallel to the magnetic field of the planar reference magnetic layers 1020, 1050, 1080. In one implementation, the magnetic field of the annular free magnetic layers 1005, 1035, 1065 can be configured to switch to being substantially parallel to the magnetic field of the planar reference magnetic layers 1020, 1050, 1080 in response to a current flow in a first direction through the conductive annular layer 1010, 1040, 1070 and to switch to being substantially anti-parallel to the magnetic field of the planar reference magnetic layers 1020, 1050, 1080 in response to a current flow in a second direction through the conductive annular layer 1010, 1040, 1070.

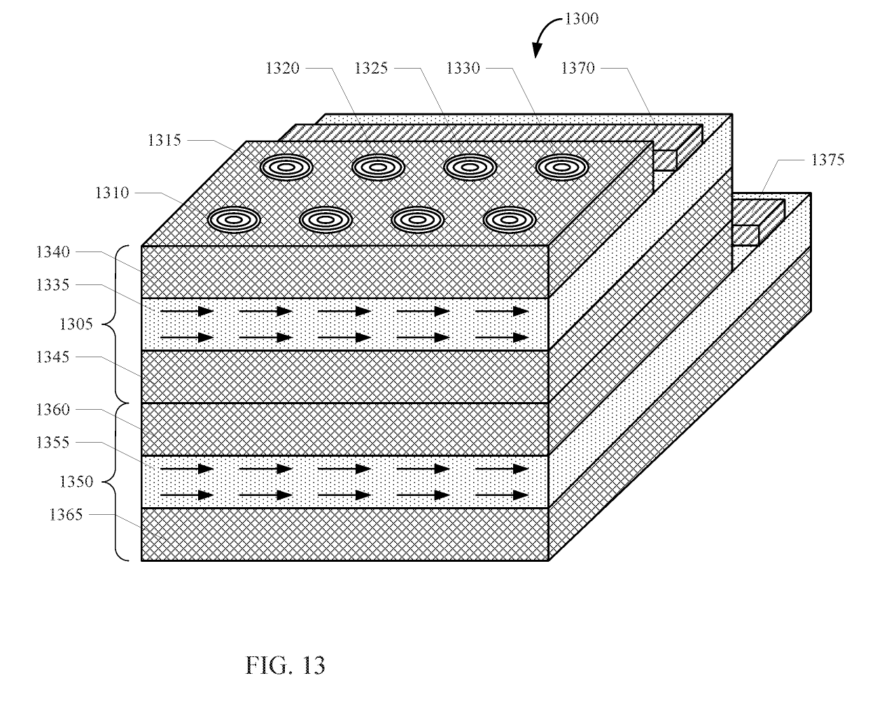

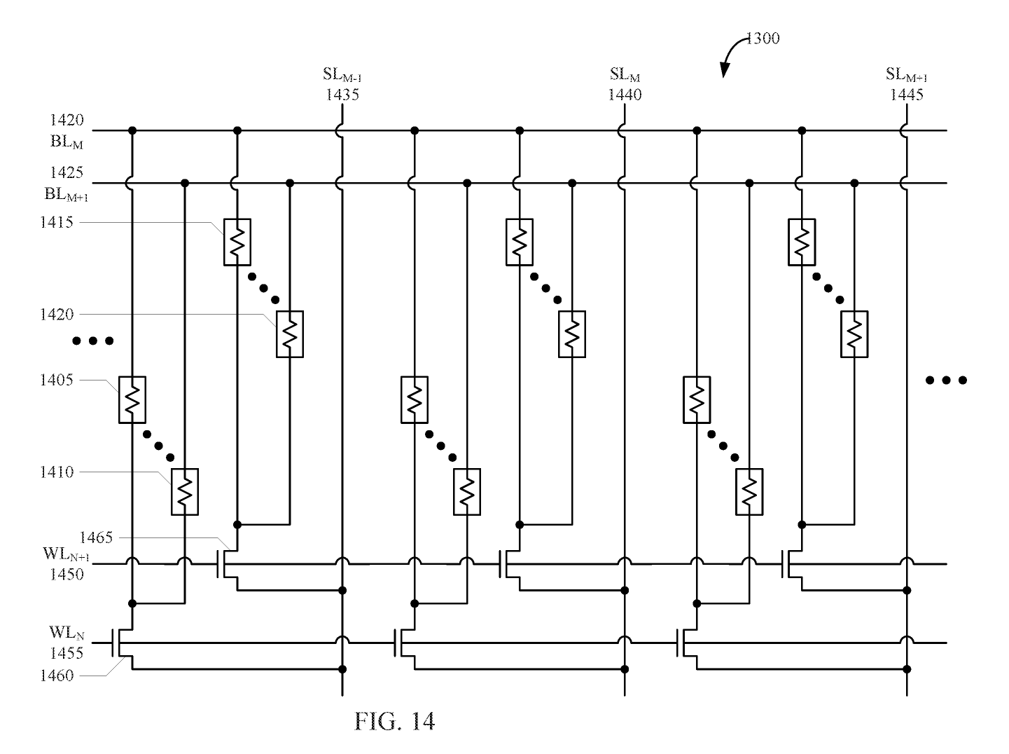

Referring now to FIG. 13, a memory device, in accordance with aspect of the present technology, is shown. The memory device can include an array of MTJ cells arranged in cell columns and cell rows in a plurality of cell levels. The MTJ cells in a given corresponding cell column position and cell row position in the plurality of cell levels can be coupled together in a cell string as described above with reference to FIGS. 10-12 in more detail.

Each MTJ cell can include an annular structure including an annular non-magnetic layer disposed about an annular conductive layer, an annular free magnetic layer disposed about the annular non-magnetic layer, and an annular tunnel insulator disposed about the annular free magnetic layer. Each MTJ cell can further include a portion of a respective planar reference magnetic layer disposed about the annular structure, a portion of a respective planar non-magnetic insulator layer disposed on a first side of the planar reference magnetic layer and about the annular structure, and a portion of another respective planar non-magnetic insulator layer disposed on a second side of the planar reference magnetic layer and about the annular structure.

For example, the MTJ cells in a first level 1305 can include a first plurality of annular structures 1310-1330 arranged in columns and rows. Each annular structure can include an annular non-magnetic layer disposed about an annular conductive layer, an annular free magnetic layer disposed about the annular non-magnetic layer, and an annular tunnel insulator disposed about the annular free magnetic layer. A first planar reference magnetic layer 1335 can be disposed about the first plurality of annular structures 1310-1330 and separated from the free magnetic layers of the first plurality of annular structures 1310-1330 by the annular tunnel barrier layers of the first plurality of annular structures 1310-1330. A first non-magnetic insulator layer 1340 can be disposed about the first plurality of annular structures 1310-1330 and on a first side of the first planar reference magnetic layer 1335. A second non-magnetic insulator layer 1345 can be disposed about the first plurality of annular structures 1310-1330 and on a second side of the first planar reference magnetic layer 1335.

The MTJ cells in a second level 1350 can include a second plurality of annular structures axially aligned with respective ones the first plurality of annular structures 1310-1330. A second planar reference magnetic layer 1355 can be disposed about the second plurality of annular structures and separated from the free magnetic layer of the second plurality of annular structures by the annular tunnel barrier layers of the second plurality of annular structures. A third non-magnetic insulator layer 1360 can be disposed about the second plurality of annular structures and between the second non-magnetic insulator layer 1345 and a first side of the second planar reference magnetic layer 1355. A fourth non-magnetic insulator layer 1365 can be disposed about the second plurality of annular structures and on a second side of the second planar reference magnetic layer 1355.

The memory device can further include MTJ cells in any number of levels. The memory device can optionally include a non-magnetic metal layer disposed between adjacent levels 1305, 1350, as described above with reference to FIG. 11. Alternatively, the memory device can optionally include a non-magnetic insulator layer and a non-magnetic metal plug disposed between adjacent levels 1305, 1355, as described above with reference to FIG. 12. The memory device can also optionally include a plurality of insulator regions disposed between portions of the planar reference magnetic layers along columns of the annular structures, as described above with reference to FIG. 6.

The memory device can also include a plurality of bit lines 1370, 1375, a plurality of source lines, a plurality of word lines, and a plurality of select transistors. The plurality of bit lines 1370, 1375 can be coupled to respective planar reference magnetic layers 1335, 1355. The annular conductive layer of each annular structure coupled together in a string can comprise a portion of a respective source line. The device 1300 will be further explained with reference to FIG. 14, which illustrates a schematic representation of the memory device.

Referring now to FIG. 14, the memory cell array 1300 can include a plurality of MTJ cells 1405-1420, a plurality of bit lines 1425, 1430, a plurality of source lines 1435-1445, a plurality of word lines 1450, 1455, and a plurality of select transistor 1460, 1465. The MTJ cells arranged along a string 1405, 1410 can be coupled by a corresponding select transistor 1460 to a respective source line 1435. The MTJ cells arranged along a second string 1415, 1420 in the same column can be coupled by another corresponding select transistor 1465 to the same respective source line 1435. The gate of the select transistors 1460, 1465 can be coupled to a respective word line 1450, 1455. The memory device can further include a plurality of memory cell array blocks, as described above with reference to FIGS. 7 and 8.

In one implementation, a logic ‘0’ state can be written to a given memory cell 1405 by biasing the respective bit line 1420 at a bit line write potential (e.g., V_{BLW}), biasing the respective source line 1435 at a ground potential, and driving the respective word line 1455 at a word line write potential (e.g., V_{WLW}=V_{Hi}). The word lines for the cells that are not being written to can be biased at a ground potential. In addition, the other source lines 1440, 1445 can be biased at a high potential or held in a high impedance state. The high potential can be equal to the bit line write potential or some portion thereof. A logic ‘1’ state can be written to the given memory cell 1405 by biasing the respective bit line 1420 at a ground potential, biasing the respective source line 1435 at a source line write potential (e.g., (V_{SLW}), and driving the respective word line 1455 at the word line write potential (e.g., V_{WLW} =V_{Hi}). The word lines for the cells that are not being written to can be biased at ground potential. In addition, the other source lines 1440, 1445 can be biased at a low potential or held in a high impedance state. The state of the given memory cell 1405 can be read by biasing the respective bit line 1420 at a bit line read potential (e.g., V_{BLR}), biasing the respective source line 1435 at a ground potential, driving the respective word line 1455 at a word line read potential (V_{WLR}=V_{Hi}), and sensing the resulting current on the respective source line 1435. The word lines for the cells that are not being read can be biased at a ground potential. In addition, the other source lines 1440, 1445 can be biased at a high potential or held in a high impedance state. The high potential can be equal to the bit line read potential or some portion thereof.

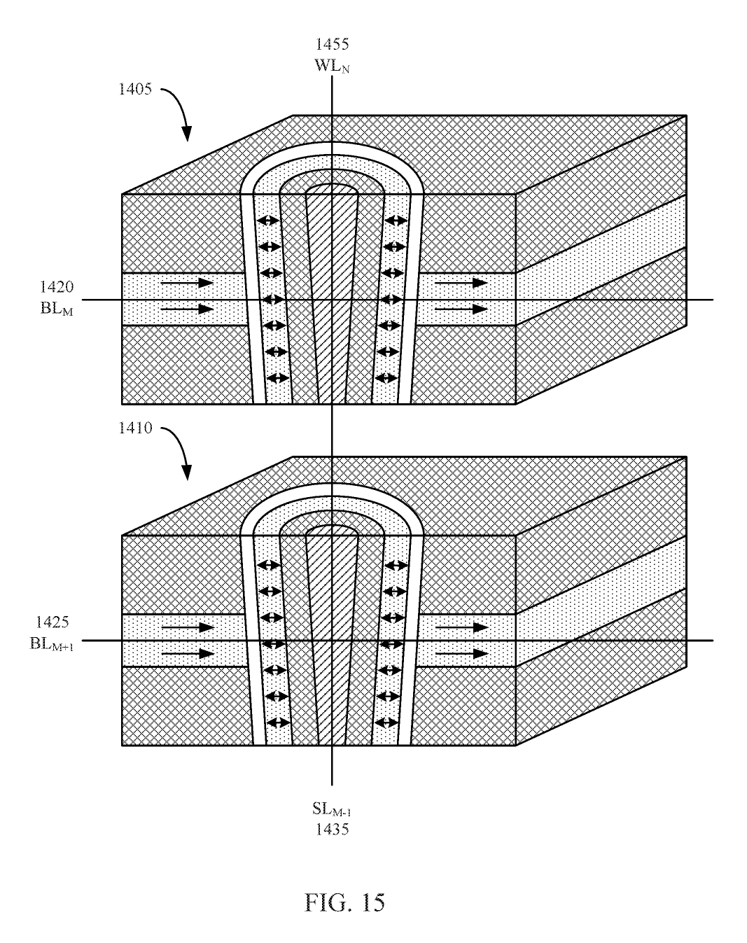

Referring now to FIG. 15, two MTJ cells coupled in a string, in accordance with aspects of the present technology, is shown. When writing a ‘0’ to a first MTJ cell 1405, the bit line 1420 can be biased at V_{BLW} and the source line can be biased at ground resulting in a current that flows from the bit line 1420 and out through the source line 1435. However, the bit lines of the second MTJ cells in the same string 1410 can be biased at ground, which will result in half the current that flows into the bit line 1420 of the first MTJ cell 1405 flowing out the source line 1435 and half the current leaking out through the bit line 1425 of the second MTJ cell. By increasing the potential voltage on the bit line 1420 of the second MTJ cell 1410 or holding the bit line 1420 of the second MTJ cell 1410 in a high impedance state (e.g., floating), the leakage current can be reduced. For example, if the potential on the bit line 1425 of the second MTJ cell 1410 is increased to one half (1/2) of the applied to the bit line 1420 of the first MTJ cell 1405, the leakage current out through the second MTJ cell 1410 can be reduced to 25%. Similar leakage paths can be present when writing a ‘1’ to a given MTJ cell in a string. By decreasing the potential applied to the bit lines of the other MTJ cells in the string or holding the bit lines of the other strings in a high impedance state, leakage currents through the other MTJ cells can be also be decreased.

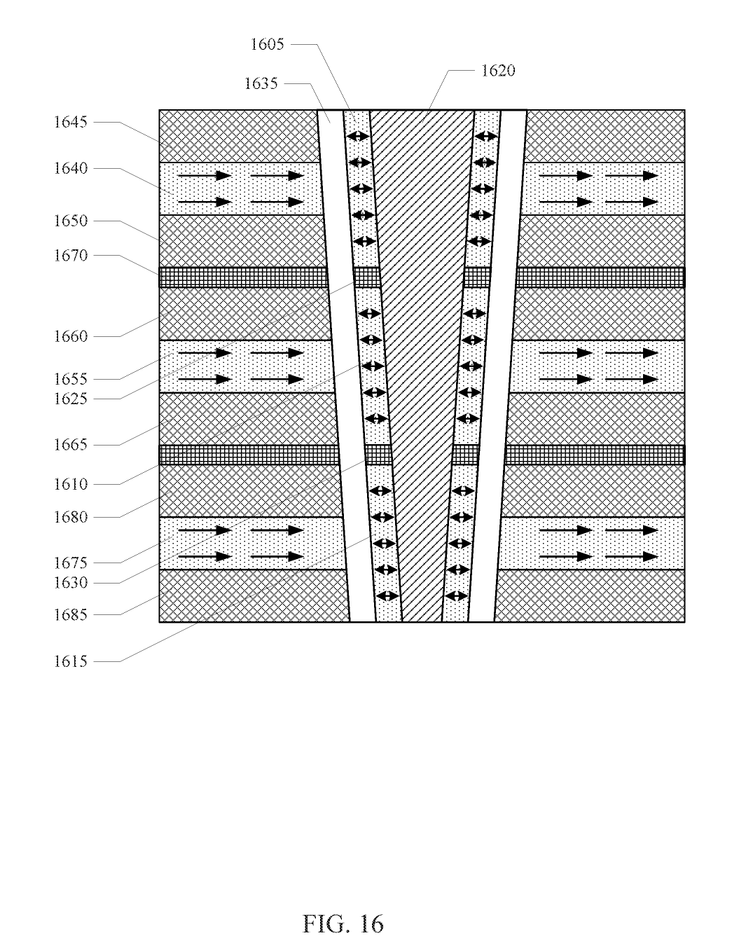

Referring now to FIG. 16, a device including a string of MTJs, in accordance with aspects, of the present technology. The device can include one or more annular structures 1605-1635 including a plurality of annular free magnetic layers 1605-1615 disposed about the annular non-magnetic layer 1620. The plurality of annular free magnetic layers 1605-1615 can be separated from each other by non-magnetic separator layers 1625, 1630. The one or more annular structures 1605-1635 can further include an annular tunnel insulator 1635 disposed about the plurality of annular free magnetic layers 1605-1615 and the one or more non-magnetic separator layers 1625, 1630. The one or more annular structures 1605-1635 can optionally include an annular non-magnetic layer (not shown) disposed between the annular conductive layer 1620 and the combination of the plurality of annular free magnetic layers 1605-1635 and one or more non-magnetic separator layers 1625, 1630.

A first planar reference magnetic layer 1640 can be disposed about the one or more annular structures 1605-1635. The first planar reference magnetic layer 1640 can be separated from the free magnetic layers 1605-1615 of the annular structures 1605-1635 by the annular tunnel barrier layer 1635. The first planar reference magnetic layer 1640 can be aligned with a first annular free magnetic layer 1605. A first non-magnetic insulator layer 1645 can be disposed about the one or more annular structures 1605-1635 and on a first side of the first planar reference magnetic layer 1640. A second non-magnetic insulator layer 1650 can be disposed about the one or more annular structures 1605-1635 and on a second side of the first planar reference magnetic layer 1640. A second planar reference magnetic layer 1655 can be disposed about the one or more annular structures 1605-1635. The second planar reference magnetic layer 1655 can be separated from the free magnetic layers 1605-1615 by the annular tunnel barrier layer 1635. The second planar reference magnetic layer 1655 can be aligned with a second annular free magnetic layer 1610. A third non-magnetic insulator layer 1660 can be disposed about the one or more annular structures 1605-1635 and on a first side of the second planar reference magnetic layer 1655. A fourth non-magnetic insulator layer 1665 can be disposed about the one or more annular structures 1605-1635 and on a second side of the second planar reference magnetic layer 1655. An optional non-magnetic metal layer 1670 can be disposed between the second non-magnetic insulator layer 1650 and the third non-magnetic insulator layer 1660.

The device can include any number of annular free magnetic layers disposed about the annular non-magnetic layer and corresponding set of planar reference magnetic layers and non-magnetic insulator layers. For example, the device can include a third planar reference magnetic layer 1675 that can be disposed about the one or more annular structures 1605-1635. The third planar reference magnetic layer 1675 can be separated from the free magnetic layers 1605-1615 of the annular structures 1605-1635 by the annular tunnel barrier layer 1635. The third planar reference magnetic layer 1675 can be aligned with a third annular free magnetic layer 1615. A fifth non-magnetic insulator layer 1680 can be disposed about the one or more annular structures 1605-1635 and on a first side of the third planar reference magnetic layer 1675. A sixth non-magnetic insulator layer 1685 can be disposed about the one or more annular structures 1605-1635 and on a second side of the third planar reference magnetic layer 1675. An optional non-magnetic metal layer can also be disposed between the fourth non-magnetic insulator layer 1665 and the fifth non-magnetic insulator layer 1680.

In one implementation, the annular structure 1605-1635 can be substantially cylindrical structures with tapered sidewalls, herein referred to as conical structures. In one implementation, the conical structures can have a taper of approximately 10-45 degrees from a first side of the planar reference magnetic layers 1640, 1655, 1675 to a second side of the planar reference magnetic layers 1640, 1655, 1675. In another expression, the wall angle measured from the normal axis to the horizontal direction of the planar reference magnetic layers 1640, 1655, 1675 can be approximately 10-45 degrees. In one implementation, the annular tunnel insulator 1635, and the annular free magnetic layer 1605, 1610, 1615 can be concentric regions each bounded by inner and outer respective tapered cylinders having substantially the same axis, disposed about a solid tapered cylindrical region of the annular conductive layer 1620.

In one implementation, the planar reference magnetic layers 1640, 1655, 1670 can include one or more layers of a Cobalt-Iron-Boron (Co—Fe—B) alloy, a Cobalt-Iron (CoFe) alloy, a Cobalt-Iron-Nickle (CoFeNi) alloy, an Iron-Nickle (FeNi) alloy, an Iron-Boron (FeB) alloy, a multilayer of Cobalt-Platinum (CoPt) and Cobalt Paradium (CoPd), a Heusler Alloy selected from Cobalt-Manganese-Silicon (CoMnSi), Cobalt-Manganese-Germanium (CoMnGe), Cobalt-Manganese-Aluminum (CoMnAl), Cobalt-Manganese-Iron-Silicon (CoMnFeSi), Cobalt-Iron-Silicon (CoFeSi), Cobalt-Iron-Aluminum (CoFeAl), Cobalt-Chromium-Iron-Aluminum (CoCrFeAl), Cobalt-Iron-Aluminum-Silicon (CoFeAlSi), or compounds thereof, with a thickness of approximately 1-20 nm, preferably 1 to 10 nm, more preferably 1 to 5 nm. The annular tunnel insulator layer 1635 can include one or more layers of Magnesium Oxide (MgO), Silicon Oxide (SiOx), Aluminum Oxide (AlOx), Titanium Oxide (TiOx), or combination of these oxide materials with a thickness of approximately 0.1-3 nm. The annular free magnetic layers 1605-1615 can include one or more layers of a Cobalt-Iron-Boron (Co—Fe—B), Cobalt Nickle Iron (CoNiFe), Nickle Iron (NiFe) alloy or their multilayer combinations with a thickness of approximately 0.5-5 nm. The non-magnetic separator layers 1625, 1630 can include an oxide alloy of Cobalt-Iron-Boron (Co—Fe—B), CoNiFe, NiFe or their multilayer combinations that also includes a non-magnetic material such as Copper (Cu), Aluminum (Al), and Ruthenium (Ru), Gallium (Ga), or Silicon (Si). The optional annular non-magnetic layer can include one or more layers of metal protecting layers that can include one or more elements of a Tantalum (Ta), Chromium (Cr), W, V, Pt, Ru, Pd, Cu, Ag, Rh, or their alloy, with a thickness of approximately 1 to 10 nm. The annular conductive layer 1620 can include one or more layers of Copper (Cu), Aluminum (Al), Ruthenium (Ru), and/or one or more alloys thereof with a thickness of approximately 5-20 nm. The non-magnetic insulator layers 1645, 1650, 1660, 1665, 1680, 1685 can include one or more layers of MgO, SiOx AlOx. are alloys thereof with a thickness of the first and second additional layers in the range of 5 to 20 nm, preferably 5 to 10 nm. The optional non-magnetic metal layers 1670 can include Nitrogen (N), Hydrogen (H), and Boron (B).

Each portion of the annular structure 1605-1635 including an annular free magnetic layer and corresponding portions of a planar reference magnetic layer and non-magnetic insulator layers aligned with the annular free magnetic layer can comprise a MTJ cell. In an in-plane magnetic field implementation, the magnetic field of the planar reference layers 1640, 1655, 1675 can have a fixed polarization substantially parallel to a major planar orientation of the planar reference magnetic layers 1640, 1655, 1675. The magnetic field of the annular free magnetic layers 1605, 1610, 1615 can have a polarization substantially parallel to the major planar orientation of the planar reference magnetic layers 1640, 1655, 1675 and selectively switchable between being substantially parallel and substantially antiparallel to the magnetic field of the planar reference magnetic layers 1640, 1655, 1675. In a perpendicular magnetic field implementation, the magnetic field of the planar reference magnetic layers 1640, 1655, 1675 can have a fixed polarization substantially perpendicular to a major planar orientation of the planar reference magnetic layers 1640, 1655, 1675. The magnetic field of the annular free magnetic layers 1605, 1610, 1615 can have a polarization substantially perpendicular to the major planar orientation of the planar reference magnetic layers 1640, 1655, 1675 and selectively switchable between being substantially parallel and substantially antiparallel to the magnetic field of the planar reference magnetic layers 1640, 1655, 1675. In one implementation, the magnetic field of the annular free magnetic layers 1605, 1610, 1615 can be configured to switch to being substantially parallel to the magnetic field of the planar reference layers 1640, 1655, 1675 in response to a current flow in a first direction through the conductive annular layer 1620 and to switch to being substantially anti-parallel to the magnetic field of the planar reference layers 1640, 1655, 1675 in response to a current flow in a second direction through the conductive annular layer 1620. Again, the in-plane magnetic field implementation can advantageously result in a 20-50% reduction in the write voltage potential, which can increase the endurance of the MTJ cell 200 by 2-6 orders of decades and or increase the write speed by 2-10 time faster as compared to the perpendicular magnetic field implementation.

The MTJ cells of a plurality of annular structures 1605-1635 can be arranged in cell columns and cell rows in a plurality of cell levels of a memory device similar to as described above in FIGS. 13 and 14. The memory device can also include a plurality of bit lines, a plurality of source lines, a plurality of word lines and a plurality of select transistors. The plurality of bit lines can be coupled to respective planar reference magnetic layers 1640, 1655, 1675. The annular conductive layer of each annular structure can comprise a portion of a respective source line. The MTJ cells arranged along an annular structure can be coupled to a corresponding select transistor 1460 to a respective source line 1435. The MTJ cells arranged along a second annular structure in the same column can be coupled by another corresponding select transistor 1465 to the same respective source line 1435. The gate of the select transistors 1460, 1465 can be coupled to a respective word line 1450, 1455. The memory device can also include a plurality of insulator regions disposed in the plurality of planar reference magnetic layers 1640, 1655, 1675 between respective pairs of columns of the plurality of annular structures 1605-1635 similar to as described above with reference to FIGS. 6 and 7. The memory device can further include a plurality of memory cell array blocks similar to as described above with reference to FIGS. 7 and 8.

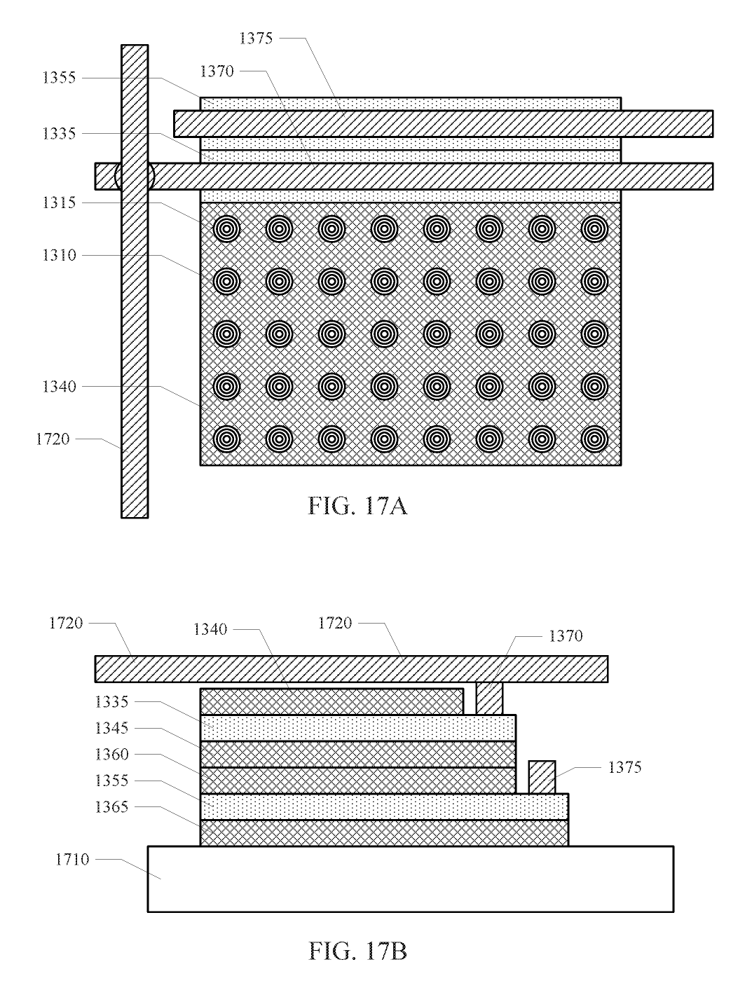

Referring now to FIGS. 17A and 17B, a memory device, in accordance with aspect of the present technology, is shown. FIGS. 17A and 17B show a top view and a right-side view of the memory device shown in FIG. 13. The memory device can include an array of MTJ cells arranged in cell columns and cell rows in a plurality of cell levels. The MTJ cells in a given corresponding cell column position and cell row position in the plurality of cell levels can be coupled together in a cell string as described above with reference to FIGS. 10-12. Alternatively, the MTJ cells can be arranged in cell columns and cell rows in a plurality of levels, wherein the MTJ cells in corresponding cell columns and cell row positions in the plurality of cell levels are coupled together in cell strings as described above with reference to FIG. 16.

In one implementation, the MTJ cells in a first level can include a first plurality of annular structures 1310-1330 arranged in columns and rows. Each annular structure can include an annular non-magnetic layer disposed about an annular conductive layer, an annular free magnetic layer disposed about the annular non-magnetic layer, and an annular tunnel insulator disposed about the annular free magnetic layer. A first planar reference magnetic layer 1335 can be disposed about the first plurality of annular structures 1310-1330 and can be separated from the free magnetic layers of the first plurality of annular structures 1310-1330 by the annular tunnel barrier layers of the first plurality of annular structures 1310-1330. A first non-magnetic insulator layer 1340 can be disposed about the first plurality of annular structures 1310-1330 and on a first side of the first planar reference magnetic layer 1335. A second non-magnetic insulator layer 1345 can be disposed about the first plurality of annular structures 1310-1330 and on a second side of the first planar reference magnetic layer 1335.

The MTJ cells in a second level can include a second plurality of annular structures axially aligned with respective ones the first plurality of annular structures 1310-1330. A second planar reference magnetic layer 1355 can be disposed about the second plurality of annular structures and can be separated from the free magnetic layer of the second plurality of annular structures by the annular tunnel barrier layers of the second plurality of annular structures. A third non-magnetic insulator layer 1360 can be disposed about the second plurality of annular structures and between the second non-magnetic insulator layer 1345 and a first side of the second planar reference magnetic layer 1355. A fourth non-magnetic insulator layer 1365 can be disposed about the second plurality of annular structures and on a second side of the second planar reference magnetic layer 1355.

The multiple levels of MTJ cell array can be disposed on one or more additional layers 1710 that can include word lines, source lines, select elements, and or the like. The memory device can optionally include a non-magnetic metal layer disposed between adjacent levels 1305, 1350, as described above with reference to FIG. 11. Alternatively, the memory device can optionally include a non-magnetic insulator layer and a non-magnetic metal plug disposed between adjacent levels 1305, 1355, as described above with reference to FIG. 12. The memory device can also optionally include a plurality of insulator regions disposed between portions of the planar reference magnetic layers along columns of the annular structures, as described above with reference to FIG. 6.

In another implementation, one or more annular structures can include a plurality of annular free magnetic layers disposed about the annular non-magnetic layer. The plurality of annular free magnetic layers can be separated from each other by non-magnetic separator layers. The one or more annular structures can further include an annular tunnel insulator disposed about the plurality of annular free magnetic layers and the one or more non-magnetic separator layers. The one or more annular structures can optionally include an annular non-magnetic layer (not shown) disposed between the annular conductive layer and the combination of the plurality of annular free magnetic layers and one or more non-magnetic separator layers.

A first planar reference magnetic layer can be disposed about the one or more annular structures. The first planar reference magnetic layer can be separated from the free magnetic layers of the annular structures by the annular tunnel barrier layer. The first planar reference magnetic layer can be aligned with a first annular free magnetic layer. A first non-magnetic insulator layer can be disposed about the one or more annular structures and on a first side of the first planar reference magnetic layer. A second non-magnetic insulator layer can be disposed about the one or more annular structures and on a second side of the first planar reference magnetic layer. A second planar reference magnetic layer can be disposed about the one or more annular structures. The second planar reference magnetic layer can be separated from the free magnetic layers by the annular tunnel barrier layer. The second planar reference magnetic layer can be aligned with a second annular free magnetic layer. A third non-magnetic insulator layer can be disposed about the one or more annular structures and on a first side of the second planar reference magnetic layer. A fourth non-magnetic insulator layer can be disposed about the one or more annular structures and on a second side of the second planar reference magnetic layer. An optional non-magnetic metal layer can be disposed between the second non-magnetic insulator layer and the third non-magnetic insulator layer.

Each portion of the annular structure including an annular free magnetic layer and corresponding portions of a planar reference magnetic layer and non-magnetic insulator layers aligned with the annular free magnetic layer can comprise a MTJ cell, as described above with reference to FIG. 16. The memory device can also optionally include a plurality of insulator regions disposed between portions of the planar reference magnetic layers along columns of the annular structures, as described above with reference to FIG. 6.

The memory device can also include a plurality of bit lines 1370, 1375 disposed on and electrically coupled to respective planar reference magnetic layers 1335, 1355. For example, a first bit line 1370 can be disposed on and coupled to a first planar reference magnetic layer 1335, and a second bit line 1375 can be disposed on and coupled to a second planar reference magnetic layer 1355. In aspect, the plurality of bit lines 1370, 1375 can be disposed at a periphery of the plurality of planar reference magnetic layers 1335, 1375.

The memory device can optionally include a plurality of memory cell array blocks, as described above with reference to FIGS. 7-9. The same planar reference layer arranged in respective rows of the memory cell array blocks can be coupled together by a respective bit line. For example, the first bit line 1370 can be electrically coupled to the first planar reference magnetic layer 1335 of each block in a respective row of the memory cell array blocks. The second bit line 1375 can be electrically coupled to the second planar reference magnetic layer 1355 of each block in a respective row of the memory cell array blocks. In addition, two or more bit lines arranged in respective columns of the memory cell array blocks can be coupled together by a corresponding global bit line 1720. For example, the first bit line 1370 can be coupled by a first global bit line 1720 to other corresponding bit lines in a respective column of the memory cell array blocks.

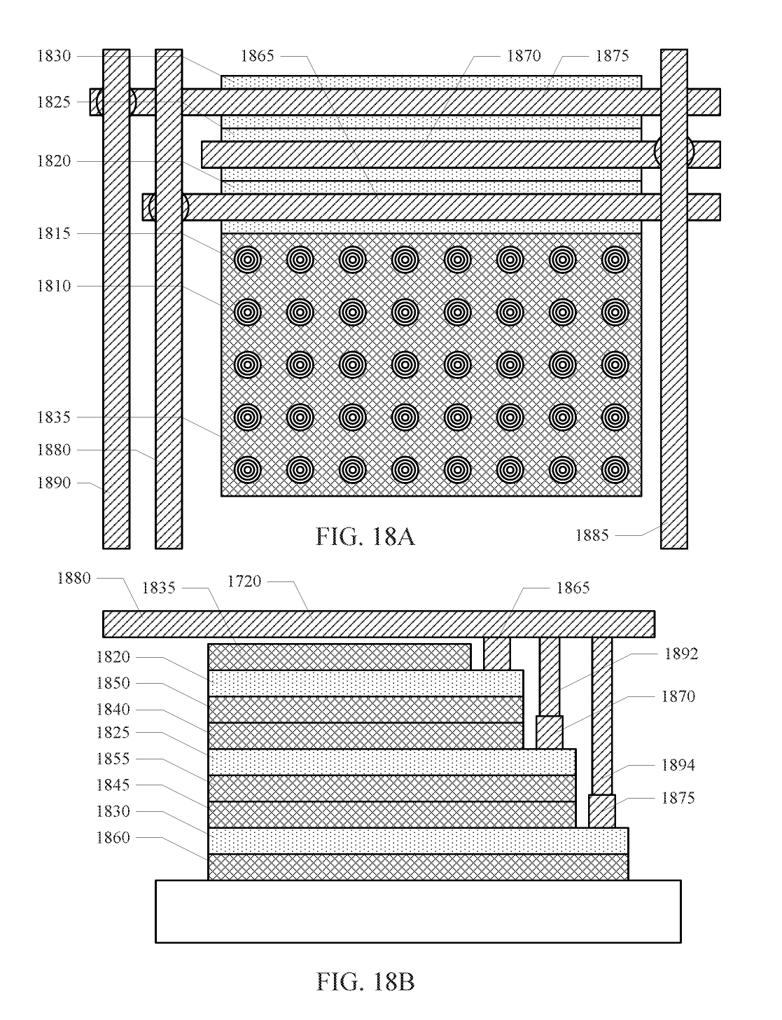

The device can be extended to include any number of planar reference magnetic layers disposed about the columns and rows of annular structures to implement strings or layers of any number of MTJ cells. For example, a memory device including strings or layers of three MTJ cells, in accordance with aspect of the present technology, is shown in FIGS. 18A and 18B. In one implementation, the MTJ cells in corresponding cell column and cell row positions in a plurality of cell levels can be coupled together in cell strings. Each MTJ cell can include an annular structure 1810, 1815 that includes an annular non-magnetic layer disposed about the annular non-magnetic layer, and an annular tunnel insulator disposed about the annular free magnetic layer. Portions of respective planar reference magnetic layers 1820, 1825, 1830 can be disposed about the annular structures 1810, 1815. Respective planar non-magnetic insulator layers 1835, 1840, 1845 can be disposed on a first side of the planar reference magnetic layers 1820, 1825, 1830 and about the annular structures 1810, 1815. Respective planar non-magnetic insulator layers 1850, 1855, 1860 can also be disposed on a second side of the planar reference magnetic layers 1820-1830 and about the annular structures 1810, 1815. The array of MTJ cells can also include a plurality of bit lines 1865, 1870, 1875 and a plurality of select elements. Respective bit lines 1865, 1870, 1875 can be disposed on and electrically coupled to respective planar magnetic layers 1820, 1825, 1830 of respective cell levels. For example, a first bit line 1865 can be disposed on and electrically coupled to a first planar reference magnetic layer 1820, a second bit line 1870 can be disposed on and electrically coupled to a second planar reference magnetic layer 1825, and a third bit line 1875 can be disposed on and electrically coupled to a third planar reference magnetic layer 1830 of each block in a respective row of memory cell array blocks. In addition, two or more bit lines arranged in respective columns of the memory cell array blocks can be coupled together by a corresponding global bit line 1880, 1885, 1890 as described above with reference to FIGS. 8 and 9. For example, the first bit line 1865 can be coupled by a first global bit line 1880 to other corresponding bit lines in a respective column of the memory cell array blocks. The second bit line 1870 can be coupled by a via 1892 to a second global bit line 1885 and similarly to other corresponding bit lines in a respective column of the memory cell array blocks. The third bit line 1875 can be coupled by a via 1894 to a third global bit line 1890 and similarly to other corresponding bit lines in a respective column of the memory cell array blocks.

In another implementation, the MTJ cells in each cell string can include an annular structure 1810, 1815 that includes an annular non-magnetic layer disposed about an annular conductive layer, a plurality of annular free magnetic layers disposed about the annular non-magnetic layer, the annular free magnetic layer separated from each other by corresponding ones of a plurality of non-magnetic separator layers, and an annular tunnel insulator disposed about the annular free magnetic layer. A portion of corresponding ones of planar reference magnetic layers 1820, 1825, 1830 can be disposed about the annular structures 1810, 1815 and aligned with corresponding ones of the plurality of portions of the free magnetic layer. Planar non-magnetic insulator layers 1835, 1840, 1845 can be disposed on a first side of each of the plurality of planar reference magnetic layers 1820, 1825, 1830 and about the annular structure 1810, 1815. Other planar non-magnetic insulator layers 1850, 1855, 1860 can be disposed on a second side of each of the plurality of planar reference magnetic layers 1820, 1825, 1830 and about the annular structure 1810, 1815. The array of MTJ cells can also include a plurality of bit lines 1865, 1870, 1875 and a plurality of select elements. Respective bit lines 1865, 1870, 1875 can be disposed on and electrically coupled to respective planar magnetic layers 1820, 1825, 1830 of respective cell levels. Again, for example, a first bit line 1865 can be disposed on and electrically coupled to a first planar reference magnetic layer 1820, a second bit line 1870 can be disposed on and electrically coupled to a second planar reference magnetic layer 1825, and a third bit line 1875 can be disposed on and electrically coupled to a third planar reference magnetic layer 1830 of each block in a respective row of memory cell array blocks. In addition, two or more bit lines arranged in respective columns of the memory cell array blocks can be coupled together by a corresponding global bit line 1880, 1885, 1890 as described above with reference to FIGS. 8 and 9. For example, the first bit line 1865 can be coupled by a first global bit line 1880 to other corresponding bit lines in a respective column of the memory cell array blocks. The second bit line 1870 can be coupled by a via 1892 to a second global bit line 1885 and similarly to other corresponding bit lines in a respective column of the memory cell array blocks. The third bit line 1875 can be coupled by a via 1894 to a third global bit line 1890 and similarly to other corresponding bit lines in a respective column of the memory cell array blocks.

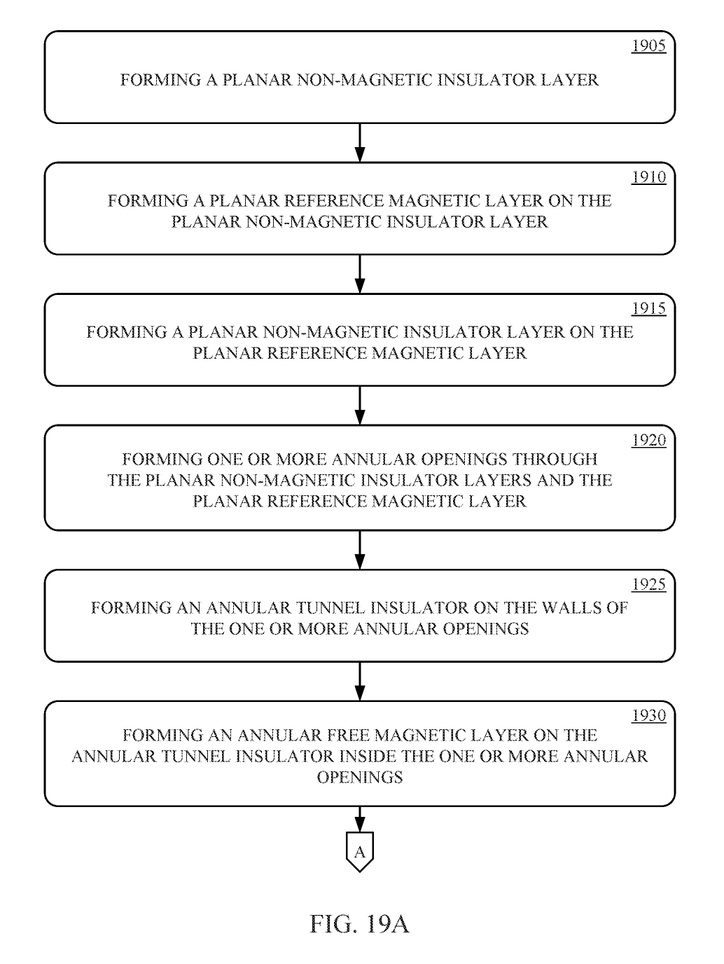

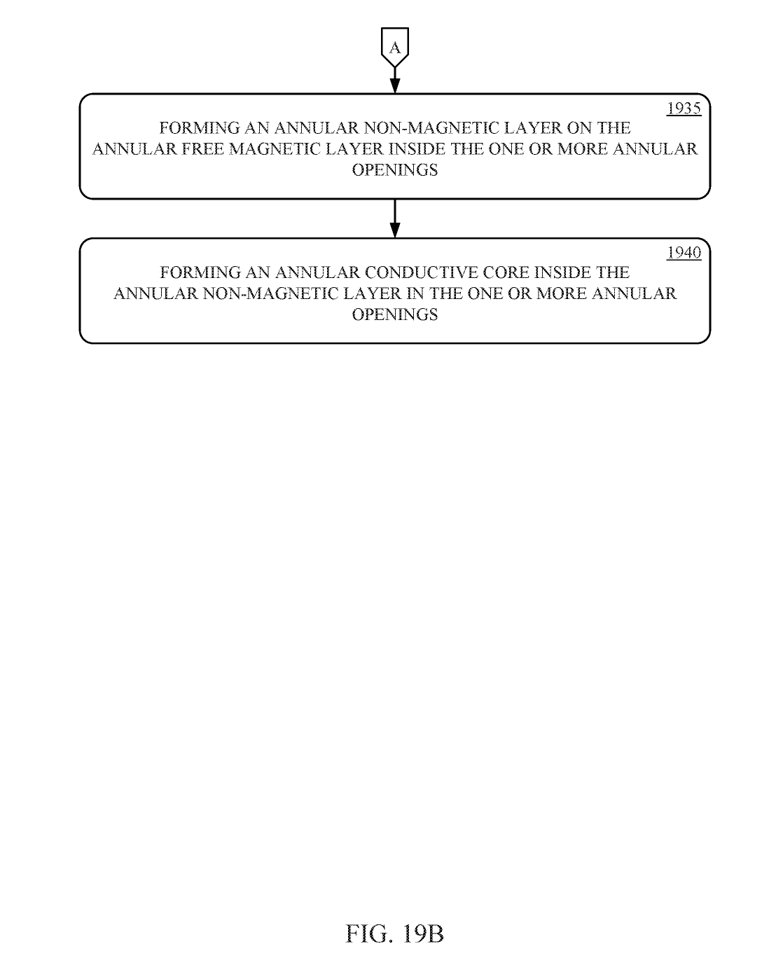

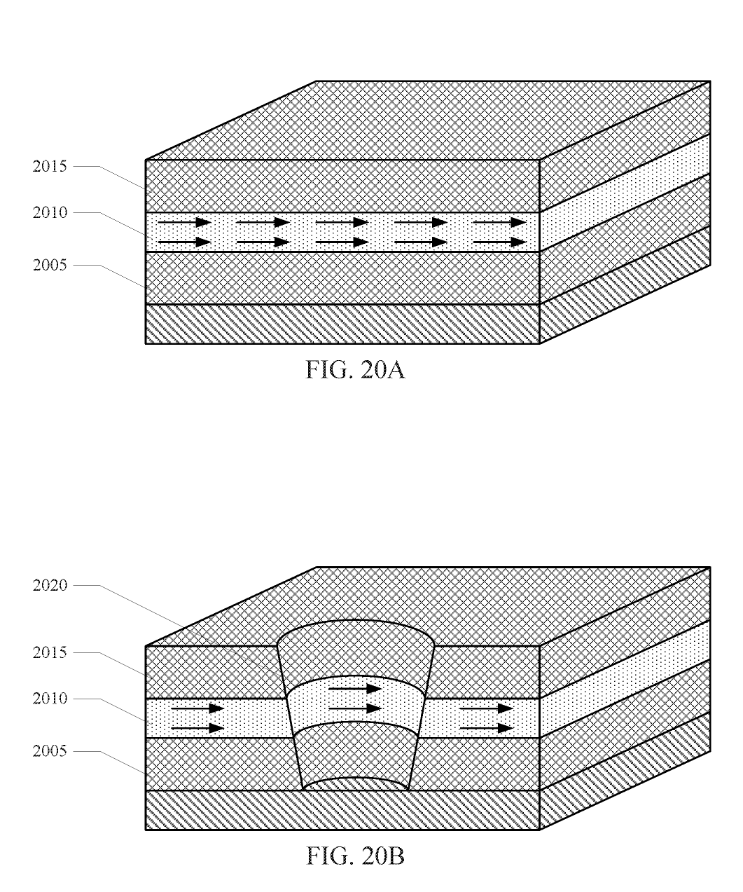

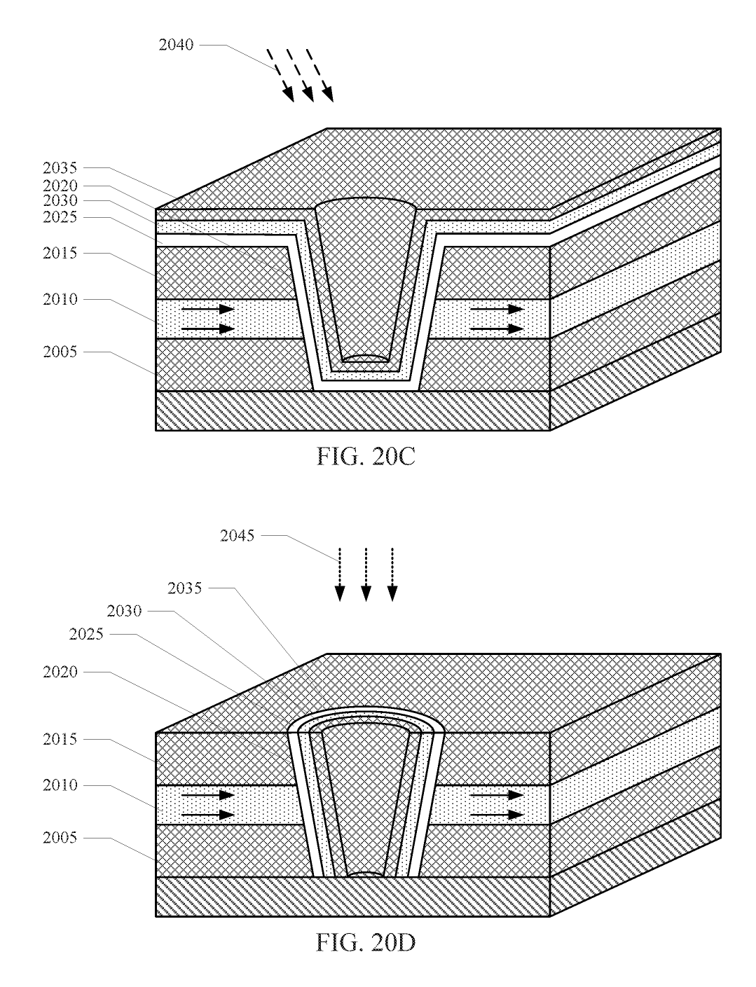

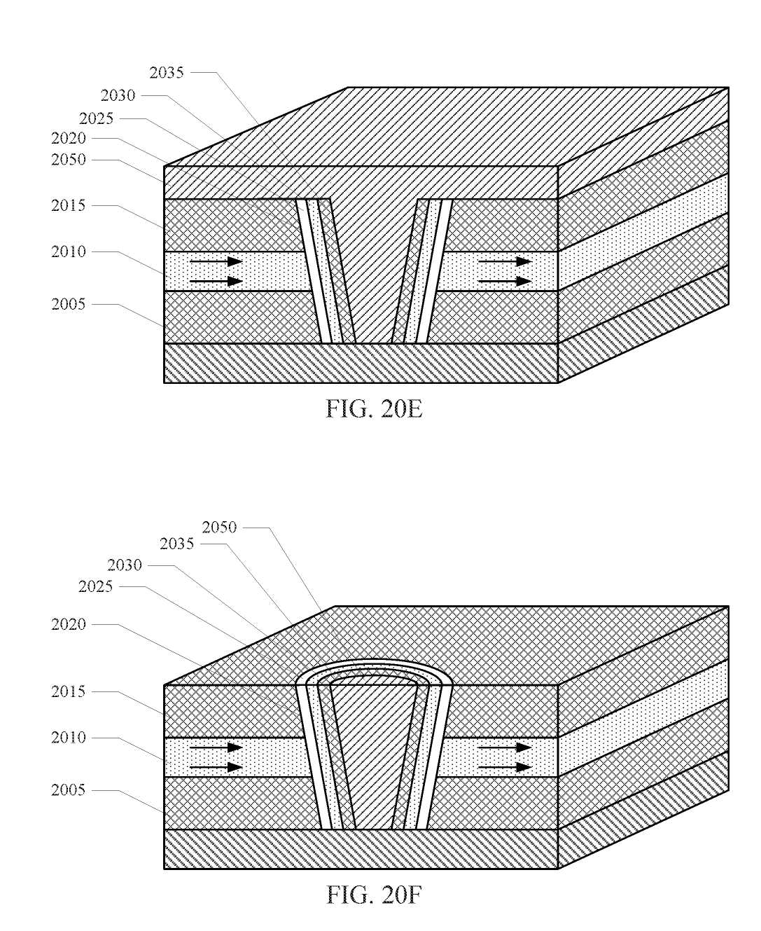

Referring now to FIGS. 19A-19B, a method of fabricating a Magnetic Tunnel Junction (MTJ) in accordance aspects of the present technology, is shown. The method of fabrication can include forming one or more planar non-magnetic insulator layers, at 1905. In one implementation, one or more layers of Magnesium Oxide (MgO), Silicon Oxide (SiOx), Aluminum Oxide (AlOx) or alloys thereof can be deposited on a substrate or other integrated circuit layer. At 1910, one or more planar reference magnetic layers can be deposited on the one or more planar non-magnetic insulator layers. In one implementation, one or more layers Cobalt-Iron-Boron (Co—Fe—B) alloy, a Cobalt-Iron (CoFe) alloy, a Cobalt-Iron-Nickle (CoFeNi) alloy, an Iron-Nickle (FeNi) alloy, an Iron-Boron (FeB) alloy, a multilayer of Cobalt-Platinum (CoPt) and Cobalt Paradium (CoPd), a Heusler Alloy selected from Cobalt-Manganese-Silicon (CoMnSi), Cobalt-Manganese-Germanium (CoMnGe), Cobalt-Manganese-Aluminum (CoMnAl), Cobalt-Manganese-Iron-Silicon (CoMnFeSi), Cobalt-Iron-Silicon (CoFeSi), Cobalt-Iron-Aluminum (CoFeAl), Cobalt-Chromium-Iron-Aluminum (CoCrFeAl), Cobalt-Iron-Aluminum-Silicon (CoFeAlSi), or compounds thereof can be deposited on the one or more planar non-magnetic insulator layers. At 1915, one or more planar non-magnetic insulator layers can be deposited on the one or more planar reference magnetic layers. In one implementation, one or more layers of MgO, SiOx, AlOx or alloys thereof can be deposited on the one or more planar reference magnetic layers. Accordingly, one or more planar non-magnetic insulator layers 2005 can be disposed on a first side of the one or more planar reference magnetic layer 2010, and one or more other planar non-magnetic insulator layers 2015 can be disposed on a second side of the one or more planar reference magnetic layers 2010 as illustrated in FIG. 20A. The magnetic field of the planar reference magnetic layer 2010 can have a fixed polarization substantially parallel to a major planar orientation of the planar reference magnetic layer 2010.

At 1920, one or more annular openings can be formed through the planar non-magnetic insulator layers and the planar reference magnetic layer. The annular openings 2020 can be substantially cylindrical with tapered sidewalls, as illustrated in FIG. 20B. The annular openings can have a taper of approximately 10-45 degrees from a first side of the planar reference magnetic layer to a second side of the planar reference magnetic layer. In another expression, the wall angle measured from the normal axis to the horizontal direction of the planar reference magnetic layer can be approximately 10-45 degrees.

At 1925, an annular tunnel insulator can be formed on the walls of the one or more annular openings. At 1930, an annular free magnetic layer can be formed on the annular tunnel insulator inside the one or more annular openings. In a first implementation, a magnetic field of the annular free magnetic layer can be formed having a polarization substantially parallel to the major planar orientation of the planar reference magnetic layer and substantially perpendicular to the walls of the one or more annular openings. In a second implementation, the magnetic field of the annular free magnetic layer can be formed having a polarization substantially perpendicular to the major planar orientation of the planar reference magnetic layer and substantially parallel to the walls of the one or more annular openings. At 1935, an annular non-magnetic layer can be formed on the annular free magnetic layer inside the one or more annular openings. In one implementation, an annular tunnel insulator layer 2025 can be deposited on the surface of the planar non-magnetic insulator layer 2015 and the sidewalls of the one or more annular openings 2020, as illustrated in FIG. 20C. The annular tunnel insulator layer can include one or more layers of a Magnesium Oxide (MgO), Silicon Oxide (SiOx), Aluminum Oxide (AlOx), Titanium Oxide (TiOx) or a combination of these oxide materials. An annular free magnetic layer 2030 can be deposited on the surface of the annular tunnel insulator layer 2025 inside and outside the one or more annular openings 2020. The annular free magnetic layer can include one or more layers of a Cobalt-Iron-Boron (Co—Fe—B), Cobalt-Nickle-Iron (CoNiFe), Nickle-Iron (NiFe) alloy or their multilayer combinations. The magnetic field of the annular free magnetic layer 2030 can be selectively switchable between being substantially parallel and substantially antiparallel to the magnetic field of the planar reference magnetic layer 2010. An annular non-magnetic layer 2035 can be deposited on the surface of the annular free magnetic layer 2030 inside and outside of the one or more annular openings 2020. The annular non-magnetic layer can include one or more layers of that can include one or more elements of a Tantalum (Ta), Chromium (Cr), W, V, Pt, Ru, Pd, Cu, Ag, Rh, or their alloy. The materials of the annular tunnel insulator 2025, the annular free magnetic layer 2030 and the annular non-magnetic layer 2035 can be deposited by an angular deposition process 2040 to improve deposition in the annular openings, as illustrated in FIG. 20C. The portions of the annular tunnel insulator layer 2025, the annular free magnetic layer 2030 and the annular non-magnetic layer 2035 at the bottom of the one or more annular openings 2020 and on top of the planar non-magnetic insular layer 2015 can be removed by one or more selective etching, milling or the like processes 2045, as illustrated in FIG. 20D. Alternatively, the portions of the annular tunnel insulator layer, the annular free magnetic layer and the annular non-magnetic layer at the bottom of the one or more annular openings and on top of the planar non-magnetic insular layers can be removed by successive etching, milling or the like processes before the subsequent layer is deposited.

At 1940, an annular conductive core can be formed inside the annular non-magnetic layers in the one or more annular openings. In one implementation, an annular conductive core layer 2040 can be deposited on the surface of the annular magnetic layer 2015 inside and outside of the one or more annular openings 2020, as illustrated in FIG. 20E. The annular conductive core can include one or more layers of Copper (Cu), Aluminum (Al), Ruthenium (Ru), and/or one or more alloys thereof. Excess material of the annular conductive core layer 2050 can be removed by Chemical Mechanical Polishing (CMP) or other similar process to form annular conductive cores 2050 in the one or more annular openings 2020, as illustrated in FIG. 20F. The processes of 1905 through 1940 can optionally be repeated a plurality of times to form a string of MTJs as illustrated in FIG. 10.

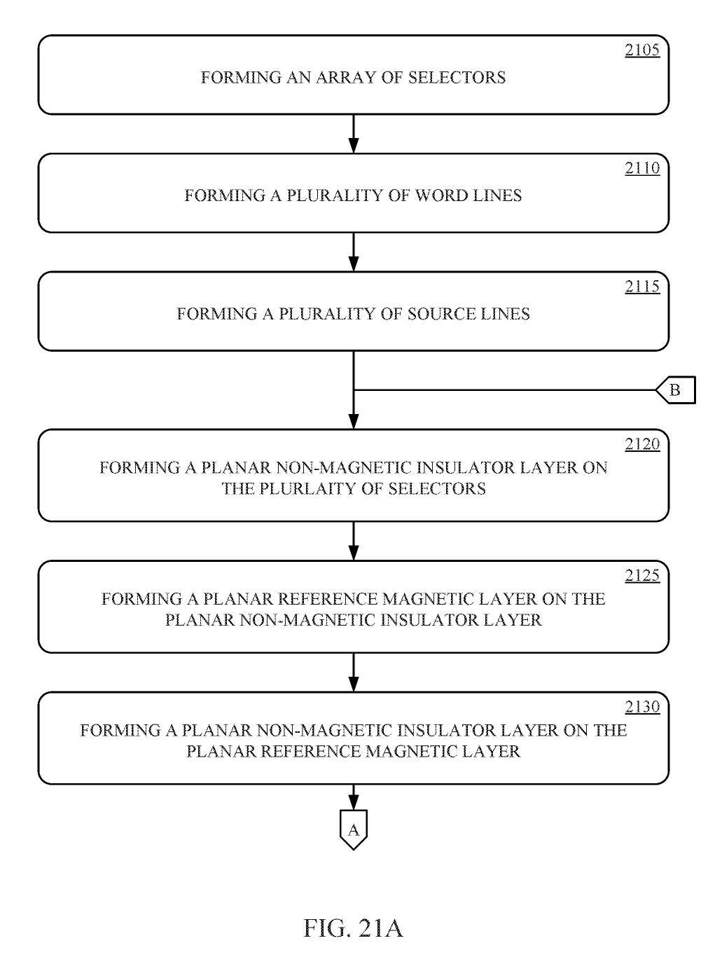

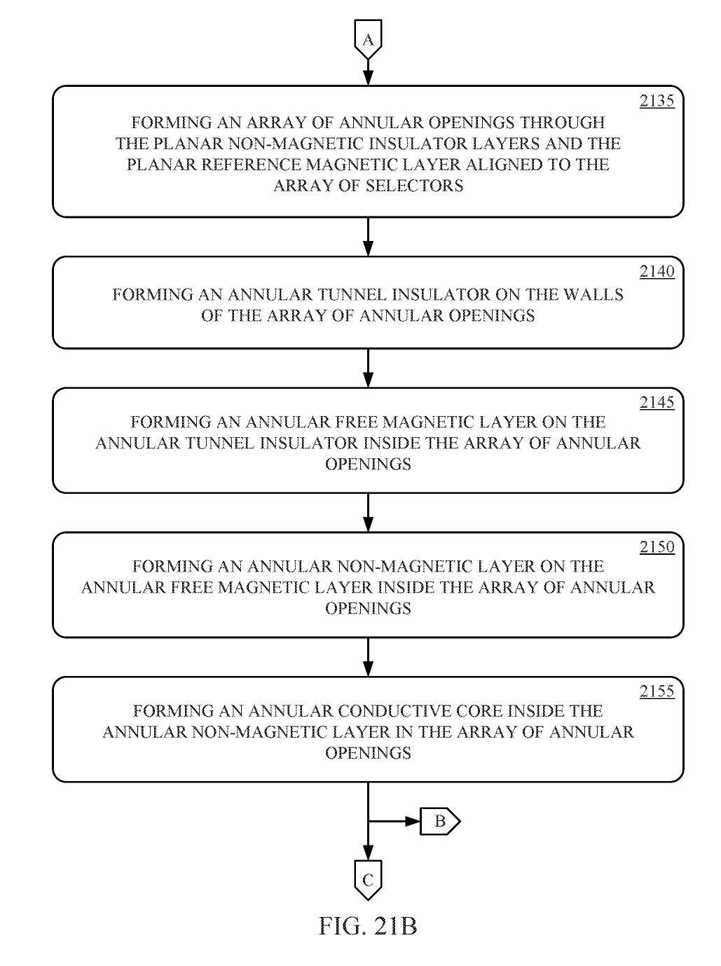

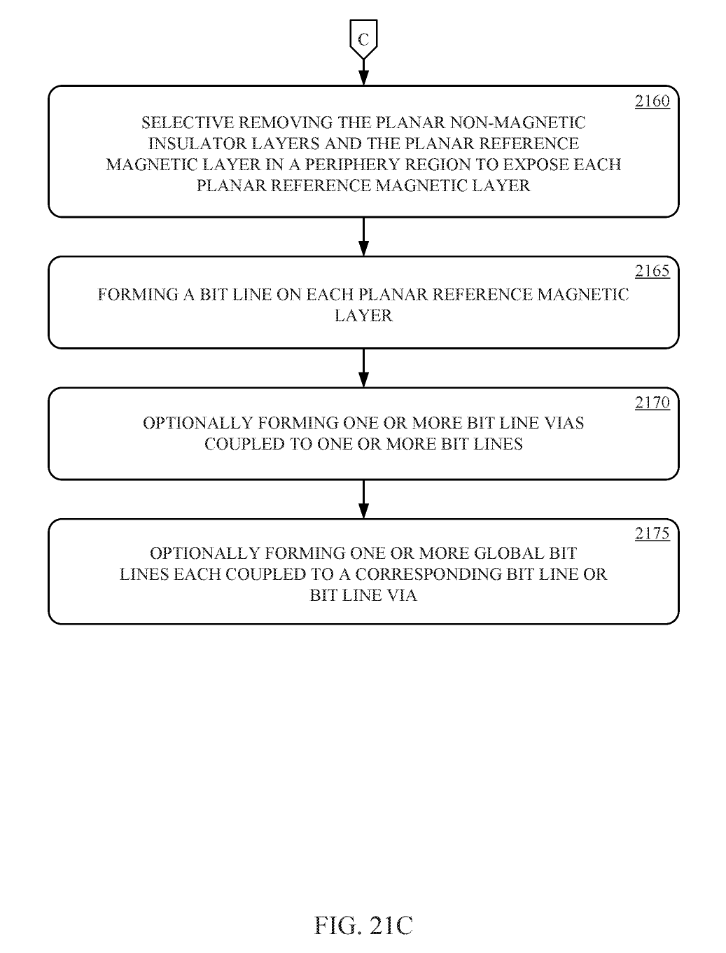

Referring now to FIGS. 21A-21C, a method of fabricating a memory cell array, in accordance with aspects of the present technology, is shown. The method of fabrication can include forming an array of selectors on a substrate, at 2105. There a numerous selectors and methods of fabrication that can be utilized for the array of selectors. The specific selector and processes are not germane to an understanding of aspects of the present technology and therefore will not be described in further detail.

At 2010, a plurality of word lines can be formed on a substrate and coupled to the selectors in respective rows. In one implementation, a conductive layer can be deposited on a substrate. A word line pattern mask can be formed on the conductive layer and a selective etching process can be performed to remove the portions of the conductive layer exposed by the word line pattern mask to form the plurality of word lines coupled to the selectors. In another embodiment, a word line can be formed by electro-plating on to the framed photo-resist pattern that has a vacancy for word line portions. The word lines can be disposed as a plurality of substantially parallel traces in a first direction (e.g., rows) of the substrate. There are numerous conductive materials that can be utilized for the word lines, and there are numerous deposition, masking, etching, photoresist-framing, and electro-plating process that can be utilized for forming the plurality of word lines. The specific materials and processes are not germane to an understanding of aspects of the present technology and therefore will not be described in further detail.

At 2115, a plurality of source lines can be formed on the substrate and coupled to the selectors in respective columns. In one implementation, an insulator layer can be formed over the plurality of word lines, and a second conductive layer can be deposited over the insulator layer. A source line pattern mask can be formed on the second conductive layer and a selective etching process can be performed to remove the portions of the second conductive layer exposed by the word line pattern mask to form the plurality of source lines. The source lines can be disposed as a plurality of substantially parallel traces in a second direction (e.g., columns) on the substrate that is perpendicular to the first direction of the word lines. There are numerous conductive materials that can be utilized for the source lines, and there are numerous deposition, masking, etching, photoresist-framing, and electro-plating process that can be utilized for forming the plurality of source lines. The specific materials and processes are not germane to an understanding of aspects of the present technology and therefore will not be described in further detail.

At 2120, one or more planar non-magnetic insulator layers can be deposited on the plurality of selectors. In one implementation, one or more layers of Magnesium Oxide (MgO), Silicon Oxide (SiOx), Aluminum Oxide (AlOx) or alloys thereof can be deposited on the plurality of selectors. At 2125, one or more planar reference magnetic layers can be deposited on the one or more planar non-magnetic insulator layers. In one implementation, one or more layers Cobalt-Iron-Boron (Co—Fe—B) alloy, a Cobalt-Iron (CoFe) alloy, a Cobalt-Iron-Nickle (CoFeNi) alloy, an Iron-Nickle (FeNi) alloy, an Iron-Boron (FeB) alloy, a multilayer of Cobalt-Platinum (CoPt) and Cobalt Paradium (CoPd), a Heusler Alloy selected from Cobalt-Manganese-Silicon (CoMnSi), Cobalt-Manganese-Germanium (CoMnGe), Cobalt-Manganese-Aluminum (CoMnAl), Cobalt-Manganese-Iron-Silicon (CoMnFeSi), Cobalt-Iron-Silicon (CoFeSi), Cobalt-Iron-Aluminum (CoFeAl), Cobalt-Chromium-Iron-Aluminum (CoCrFeAl), Cobalt-Iron-Aluminum-Silicon (CoFeAlSi), or compounds thereof can be deposited on the one or more planar non-magnetic insulator layers. At 2130, one or more planar non-magnetic insulator layers can be deposited on the one or more planar reference magnetic layers. In one implementation, one or more layers of MgO, SiOx, AlOx or alloys thereof can be deposited on the one or more planar reference magnetic layers. Accordingly, one or more planar non-magnetic insulator layers 2005 can be disposed on a first side of the one or more planar reference magnetic layer 2010, and one or more other planar non-magnetic insulator layers 2015 can be disposed on a second side of the one or more planar reference magnetic layers 2010 as illustrated in FIG. 20A. The magnetic field of the planar reference magnetic layer 2010 can have a fixed polarization substantially parallel to a major planar orientation of the planar reference magnetic layer 2010.

At 2135, an array of annular openings can be formed through the planar non-magnetic insulator layers and the planar reference magnetic layer. The array of annular openings can be aligned with the array of selectors. The annular openings 2020 can be substantially cylindrical with tapered sidewalls, as illustrated in FIG. 20B. The annular openings can have a taper of approximately 10-45 degrees from a first side of the planar reference magnetic layer to a second side of the planar reference magnetic layer. In another expression, the wall angle measured from the normal axis to the horizontal direction of the planar reference magnetic layer can be approximately 10-45 degrees.

At 2140, an annular tunnel insulator can be formed on the walls of the array of annular openings. At 2145, an annular free magnetic layer can be formed on the annular tunnel insulator inside the array of annular openings. In a first implementation, a magnetic field of the annular free magnetic layer can be formed having a polarization substantially parallel to the major planar orientation of the planar reference magnetic layer and substantially perpendicular to the walls of the one or more annular openings. In a second implementation, the magnetic field of the annular free magnetic layer can be formed having a polarization substantially perpendicular to the major planar orientation of the planar reference magnetic layer and substantially parallel to the walls of the one or more annular openings. At 2150, an annular non-magnetic layer can be formed on the annular free magnetic layer inside the array of annular openings. In one implementation, an annular tunnel insulator layer 2025 can be deposited on the surface of the planar non-magnetic insulator layer 2015 and the sidewalls of the array of annular openings 2020, as illustrated in FIG. 20C. The annular tunnel insulator layer can include one or more layers of a Magnesium Oxide (MgO), Silicon Oxide (SiOx), Aluminum Oxide (AlOx), Titanium Oxide (TiOx) or a combination of these oxide materials. An annular free magnetic layer 2030 can be deposited on the surface of the annular tunnel insulator layer 2025 inside and outside the array of annular openings 2020. The annular free magnetic layer can include one or more layers of a Cobalt-Iron-Boron (Co—Fe—B), Cobalt-Nickle-Iron (CoNiFe), Nickle-Iron (NiFe) alloy or their multilayer combinations. The magnetic field of the annular free magnetic layer 2030 can be selectively switchable between being substantially parallel and substantially antiparallel to the magnetic field of the planar reference layer 2010. An annular non-magnetic layer 2035 can be deposited on the surface of the annular free magnetic layer 2030 inside and outside of the array of annular openings 2020. The annular non-magnetic layer can include one or more layers of that can include one or more elements of a Tantalum (Ta), Chromium (Cr), W, V, Pt, Ru, Pd, Cu, Ag, Rh, or their alloy. The materials of the annular tunnel insulator 2025, the annular free magnetic layer 2030 and the annular non-magnetic layer 2035 can be deposited by an angular deposition process 2040 to improve deposition in the annular openings, as illustrated in FIG. 20C. The portions of the annular tunnel insulator layer 2025, the annular free magnetic layer 2030 and the annular non-magnetic layer 2035 at the bottom of the array of annular openings 2020 and on top of the planar non-magnetic insular layer 2015 can be removed by one or more selective etching, milling or the like processes 2045, as illustrated in FIG. 20D. Alternatively, the portions of the annular tunnel insulator layer, the annular free magnetic layer and the annular non-magnetic layer at the bottom of the array of annular openings and on top of the planar non-magnetic insular layers can be removed by successive etching, milling or the like processes before the subsequent layer is deposited.

At 2155, an annular conductive core can be formed inside the annular non-magnetic layers in the array of annular openings. The annular conductive cores in the array of annular openings can be coupled to a corresponding select transistor. In one implementation, an annular conductive core layer 2050 can be deposited on the surface of the annular magnetic layer 2015 inside and outside of the array of annular openings 2020, as illustrated in FIG. 20E. The annular conductive core can include one or more layers of Copper (Cu), Aluminum (Al), Ruthenium (Ru), and/or one or more alloys thereof. Excess material of the annular conductive core layer 2050 can be removed by Chemical Mechanical Polishing (CMP) or other similar process to form annular conductive cores 2050 in the array of annular openings 2020, as illustrated in FIG. 20F. The processes of 2120 through 2155 can optionally be repeated a plurality of times to form a string of MTJs as illustrated in FIG. 10.

At 2160, portions of one or more planar non-magnetic insulator layers and one or more planar reference magnetic layers can be removed in a periphery region to expose each planar reference magnetic layer. The periphery region can be outside the array of annular openings. In one implementation, a series of one or more etching, milling or the like processes can be used to step down through the planar non-magnetic insulator layers and the planar reference magnetic layers. At 2165, a bit line can be formed on each planar reference magnetic layer. In one implementation, a conductive layer can be deposited. A bit line pattern mask can be formed on the conductive layer and a selective etching process can be performed to remove the portions of the conductive layer exposed by the bit line pattern mask to form the plurality of bit lines on corresponding ones of the planar reference magnetic layers. In another implementation, a photo-resist frame is made by photo process before depositing a bit line material. The photo-resist frame has an opening to form a bit line inside. The electric-plating process is used to form a metal bit line inside the photo-resist frame. After the electrical plating process, the photo-resist frame is removed. The bit lines can be disposed as a plurality of substantially parallel traces in a first direction (e.g., rows) on respective planar reference magnetic layers, as illustrated in FIG. 13.

At 2170, one or more bit line vias can optionally be formed. The one or more bit line vias can be coupled to respective bit lines, as illustrated in FIGS. 18A and 18B. There are numerous conductive materials that can be utilized for the bit line vias, and there are numerous deposition, masking, and etching process that can be utilized for forming the plurality of bit line vias. The specific materials and processes are not germane to an understanding of aspects of the present technology and therefore will not be described in further detail.

At 2175, one or more global bit lines can be formed. The one or more global bit lines can be coupled to corresponding bit lines or bit line vias, as illustrated in FIGS. 7, 18A and 18B. In one implementation, two or more bit lines arranged in respective columns can be coupled together by a corresponding global bit line. There are numerous conductive materials that can be utilized for the global bit lines, and there are numerous deposition, masking, and etching process that can be utilized for forming the plurality of global bit lines. The specific materials and processes are not germane to an understanding of aspects of the present technology and therefore will not be described in further detail.

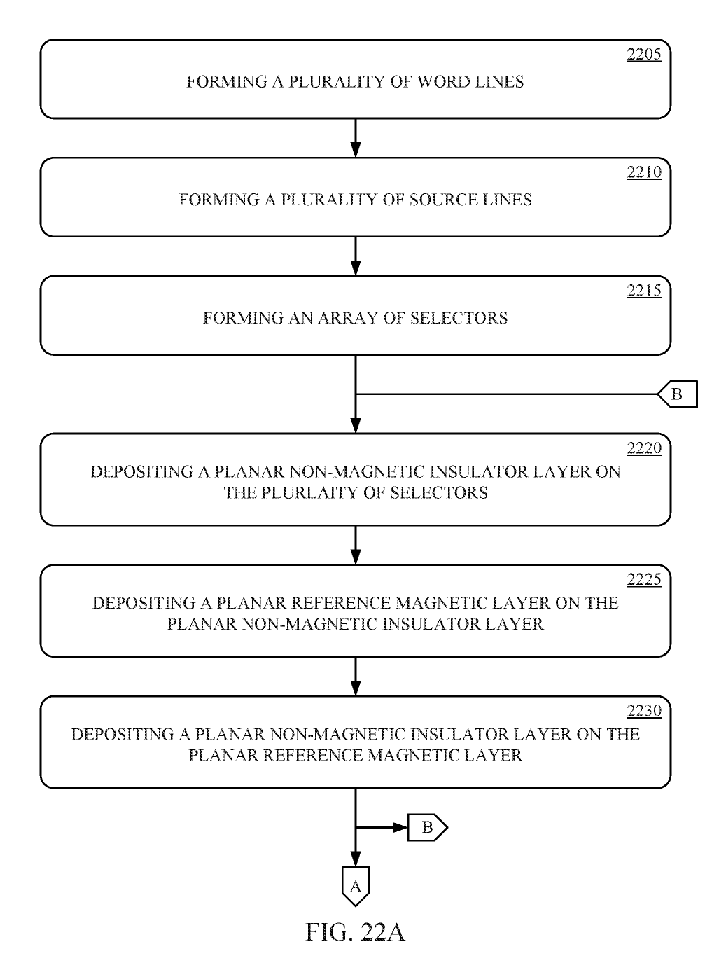

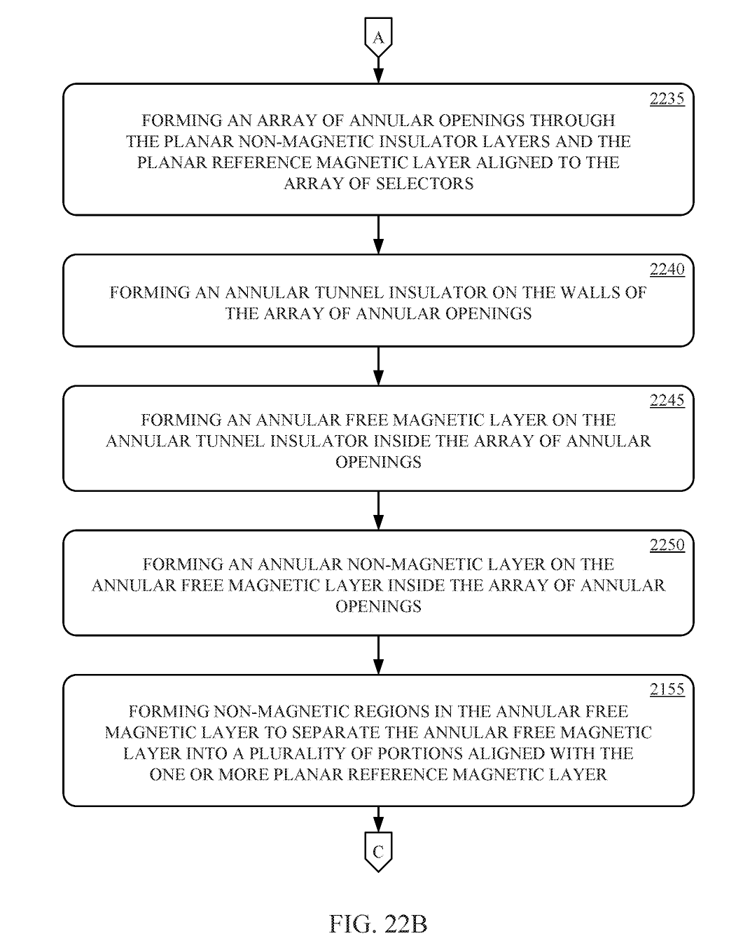

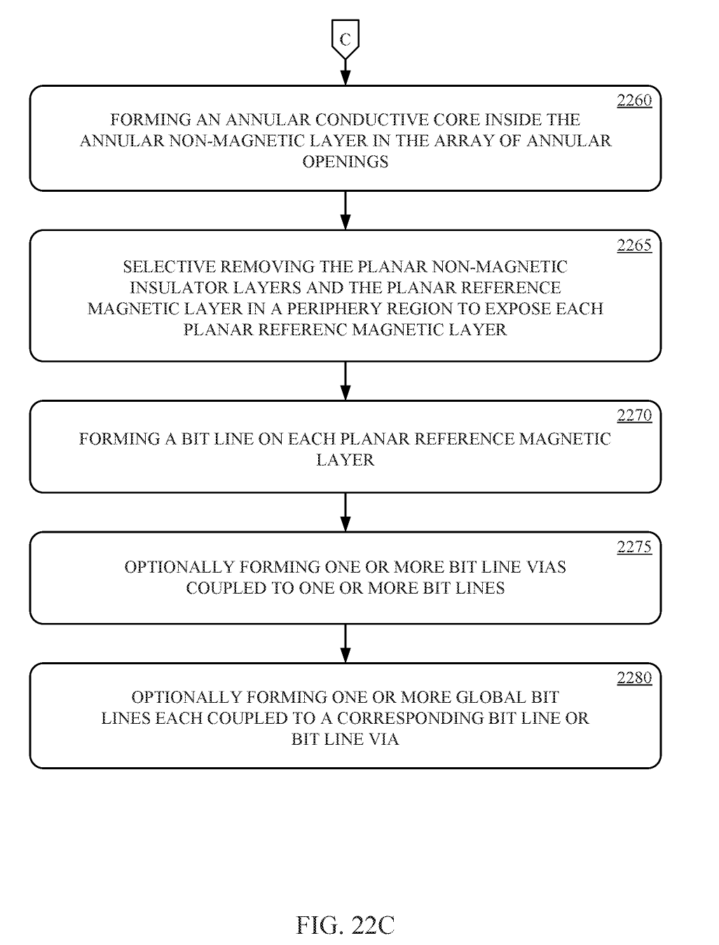

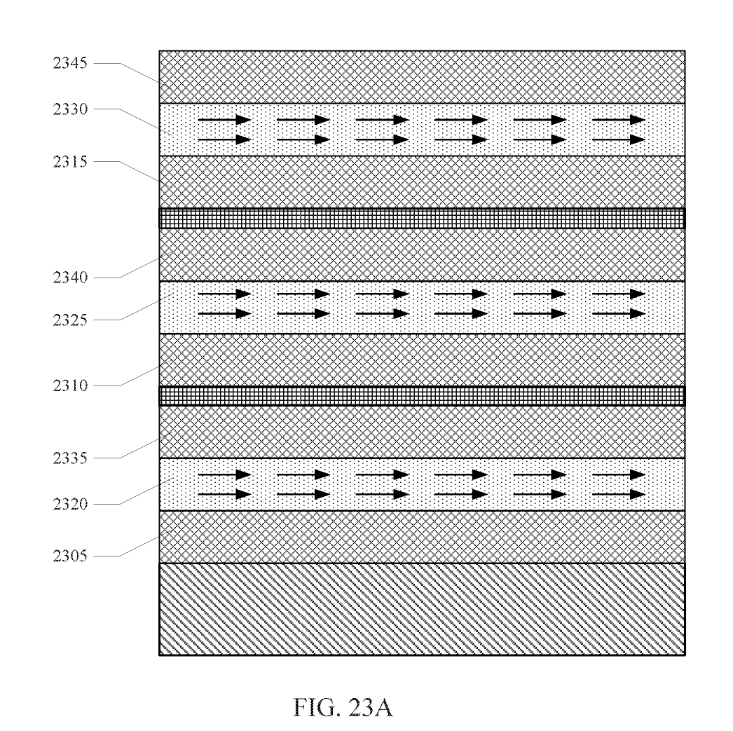

Referring now to FIGS. 22A-22C, a method of fabricating a memory cell array, in accordance with aspects of the present technology, is shown. The method of fabrication can include forming an array of selectors on a substrate, at 2205. There a numerous selectors and methods of fabrication that can be utilized for the array of selectors. The specific selector and processes are not germane to an understanding of aspects of the present technology and therefore will not be described in further detail.

At 2210, a plurality of word lines can be formed on the substrate and coupled to the selectors in respective rows. In one implementation, a conductive layer can be deposited on a substrate. A word line pattern mask can be formed on the conductive layer and a selective etching process can be performed to remove the portions of the conductive layer exposed by the word line pattern mask to form the plurality of word lines. In another embodiment, a word line can be formed by electro-plating on to the framed photo-resist pattern that has a vacancy for word line portion. The word lines can be disposed as a plurality of substantially parallel traces in a first direction (e.g., rows) of the substrate. There are numerous conductive materials that can be utilized for the word lines, and there are numerous deposition, masking, and etching process that can be utilized for forming the plurality of word lines. The specific materials and processes are not germane to an understanding of aspects of the present technology and therefore will not be described in further detail.

At 2215, a plurality of source lines can be formed on the substrate and coupled to the selectors in respective rows. In one implementation, an insulator layer can be formed over the plurality of word lines, and a second conductive layer can be deposited over the insulator layer. A source line pattern mask can be formed on the second conductive layer a selective etching process can be performed to remove the portions of the second conductive layer exposed by the word line pattern mask to form the plurality of source lines. The source lines can be disposed as a plurality of substantially parallel traces in a second direction (e.g., columns) on the substrate that is perpendicular to the first direction of the word lines. There are numerous conductive materials that can be utilized for the source lines, and there are numerous deposition, masking, and etching process that can be utilized for forming the plurality of source lines. The specific materials and processes are not germane to an understanding of aspects of the present technology and therefore will not be described in further detail.

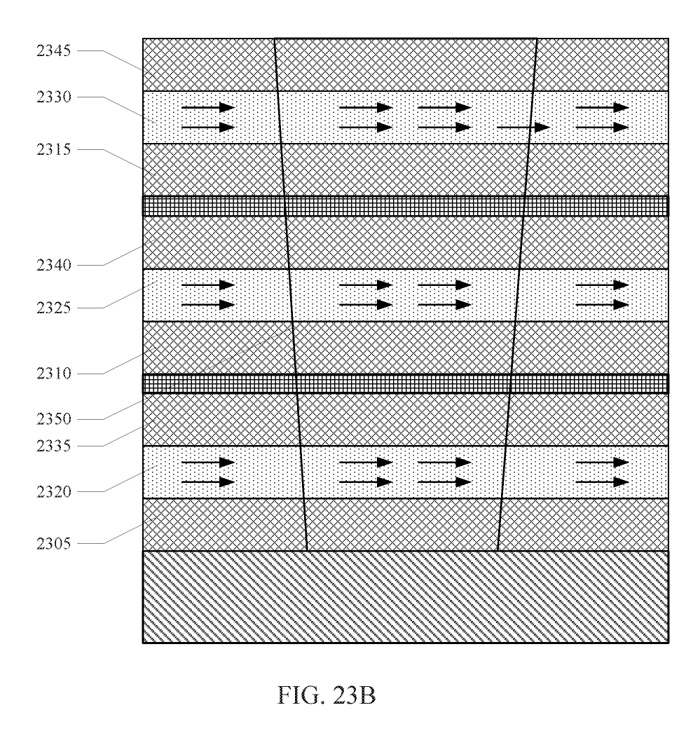

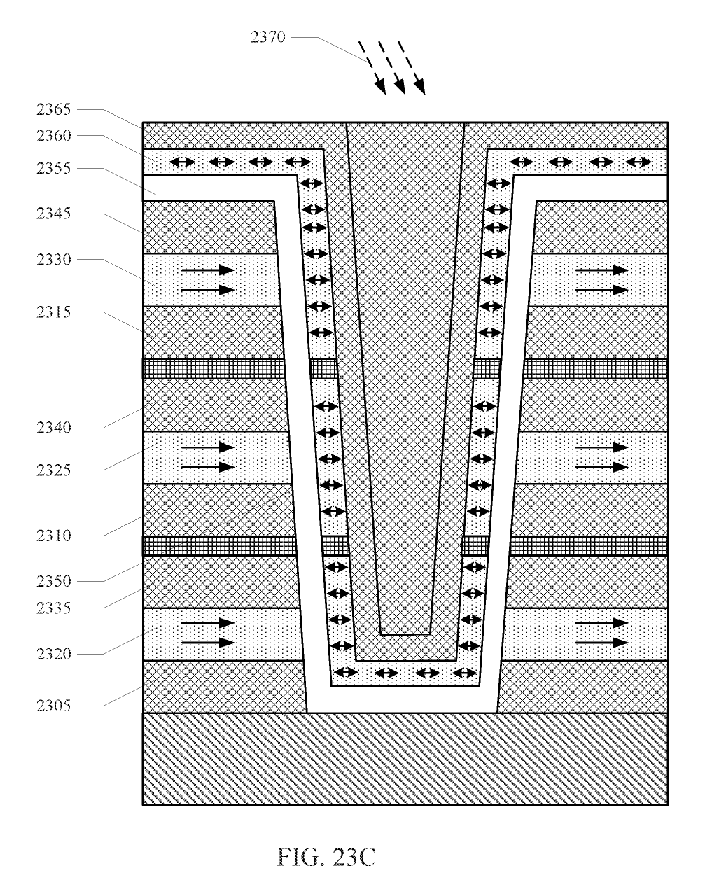

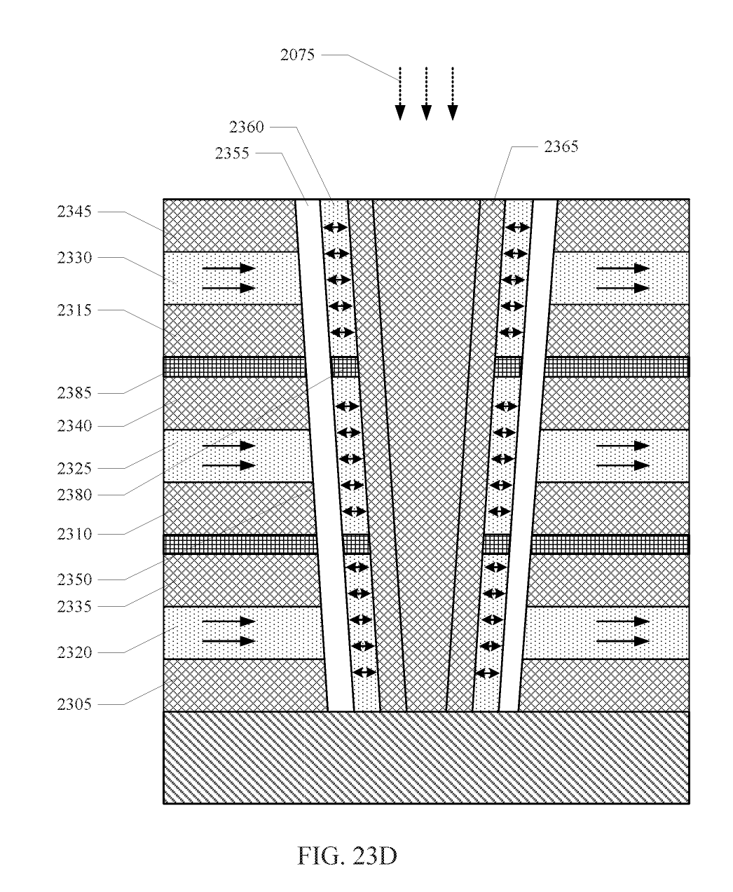

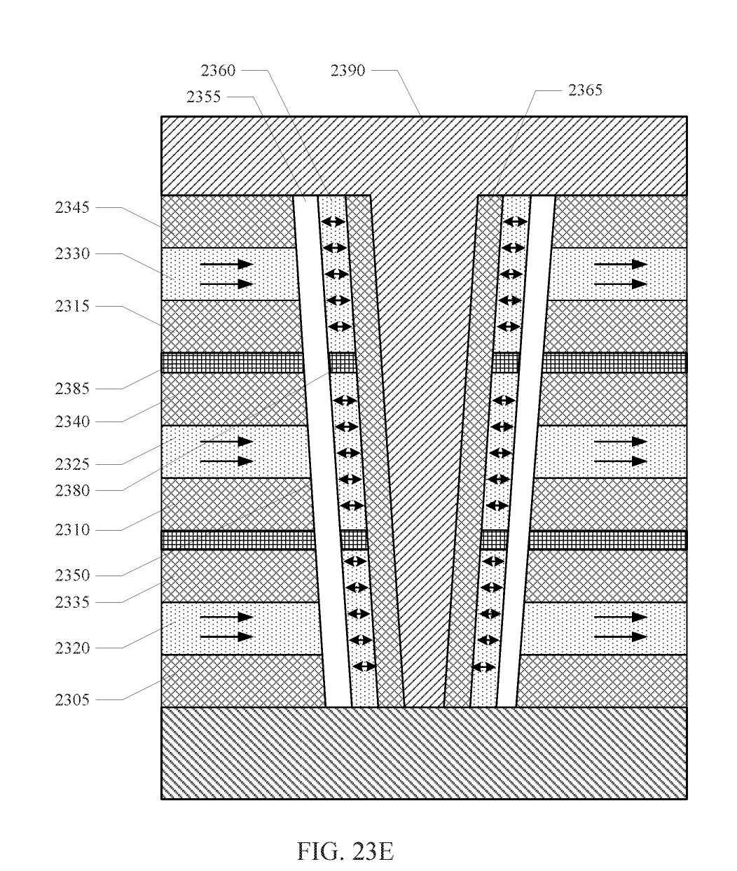

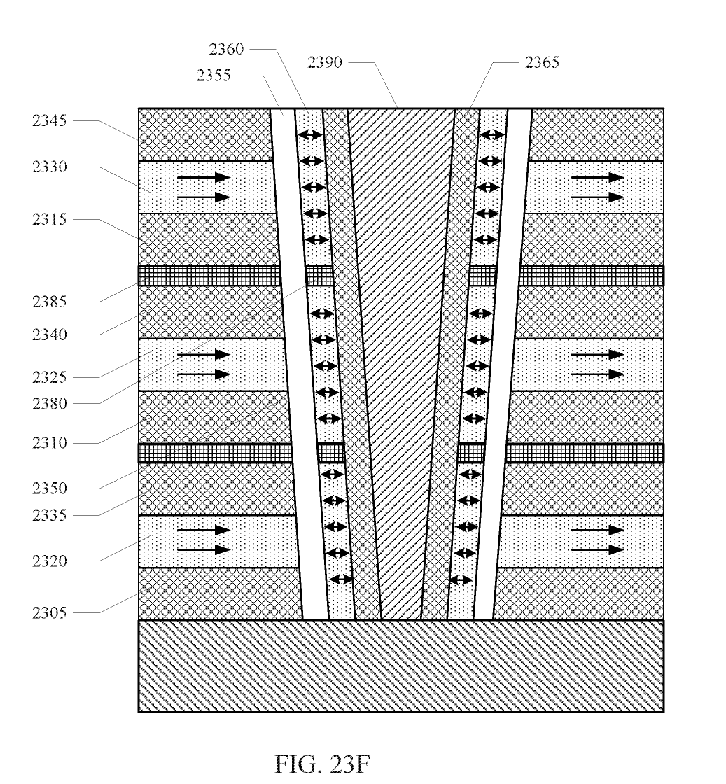

At 2220, one or more planar non-magnetic insulator layers can be deposited on the plurality of selectors. In one implementation, one or more layers of Magnesium Oxide (MgO), Silicon Oxide (SiOx), Aluminum Oxide (AlOx) or alloys thereof can be deposited on the plurality of selectors. At 2225, one or more planar reference magnetic layers can be deposited on the one or more planar non-magnetic insulator layers. In one implementation, one or more layers Cobalt-Iron-Boron (Co—Fe—B) alloy, a Cobalt-Iron (CoFe) alloy, a Cobalt-Iron-Nickle (CoFeNi) alloy, an Iron-Nickle (FeNi) alloy, an Iron-Boron (FeB) alloy, a multilayer of Cobalt-Platinum (CoPt) and Cobalt Paradium (CoPd), a Heusler Alloy selected from Cobalt-Manganese-Silicon (CoMnSi), Cobalt-Manganese-Germanium (CoMnGe), Cobalt-Manganese-Aluminum (CoMnAl), Cobalt-Manganese-Iron-Silicon (CoMnFeSi), Cobalt-Iron-Silicon (CoFeSi), Cobalt-Iron-Aluminum (CoFeAl), Cobalt-Chromium-Iron-Aluminum (CoCrFeAl), Cobalt-Iron-Aluminum-Silicon (CoFeAlSi), or compounds thereof can be deposited on the one or more planar non-magnetic insulator layers. At 2230, one or more planar non-magnetic insulator layers can be deposited on the one or more planar reference magnetic layers. In one implementation, one or more layers of MgO, SiOx, AlOx or alloys thereof can be deposited on the one or more planar reference magnetic layers. The processes of 2220 through 2230 can be repeated a plurality of times to form a string of MTJs, as illustrated in FIG. 23A. Accordingly, one or more planar non-magnetic insulator layers 2305, 2310, 2315 can be disposed on a first side of the one or more planar reference magnetic layers 2320, 2325, 2330, and one or more other planar non-magnetic insulator layers 2335, 2340, 2345 can be disposed on a second side of the one or more planar reference magnetic layers 2320, 2325, 2330, as illustrated in FIG. 23A. The magnetic field of the planar reference magnetic layers 2320, 2325, 2330 can have a fixed polarization substantially parallel to a major planar orientation of the planar reference magnetic layer 2320, 2325, 2330.

At 2235, an array of annular openings can be formed through the plurality of stacks of planar non-magnetic insulator layers and the planar reference magnetic layer. The array of annular openings can be aligned with the array of selectors. The annular openings 2350 can be substantially cylindrical with tapered sidewalls, as illustrated in FIG. 23B. The annular openings can have a taper of approximately 10-45 degrees from a first side of the planar reference magnetic layer to a second side of the planar reference magnetic layer. In another expression, the wall angle measured from the normal axis to the horizontal direction of the planar reference magnetic layer can be approximately 10-45 degrees.

At 2240, an annular tunnel insulator can be formed on the wall of the array of annular openings. At 2245, an annular free magnetic layer can be formed on the annular tunnel insulator inside the array of annular openings. In a first implementation, a magnetic field of the annular free magnetic layer can be formed having a polarization substantially parallel to the major planar orientation of the planar reference magnetic layer and substantially perpendicular to the walls of the one or more annular openings. In a second implementation, the magnetic field of the annular free magnetic layer can be formed having a polarization substantially perpendicular to the major planar orientation of the planar reference magnetic layer and substantially parallel to the walls of the one or more annular openings. At 2250, an annular non-magnetic layer can be formed on the annular free magnetic layer inside the array of annular openings. In one implementation, an annular tunnel insulator layer 2355 can be deposited on the surface of the planar non-magnetic insulator layer 2345 and the sidewalls of the array of annular openings 2350, as illustrated in FIG. 23C. The annular tunnel insulator layer can include one or more layers of a Magnesium Oxide (MgO), Silicon Oxide (SiOx), Aluminum Oxide (AlOx), Titanium Oxide (TiOx) or a combination of these oxide materials. An annular free magnetic layer 2360 can be deposited on the surface of the annular tunnel insulator layer 2355 inside and outside the array of annular openings 2350. The annular free magnetic layer can include one or more layers of a Cobalt-Iron-Boron (Co—Fe—B), Cobalt-Nickle-Iron (CoNiFe), Nickle-Iron (NiFe) alloy or their multilayer combinations. An annular free magnetic layer 2365 can be deposited on the surface of the annular free magnetic layer 2360 inside and outside of the array of annular openings 2350. The magnetic field of the annular free magnetic layer 2360 can be selectively switchable between being substantially parallel and substantially antiparallel to the magnetic field of the planar reference magnetic layers 2320, 2325, 2330. The materials of the annular tunnel insulator 2355, the annular free magnetic layer 2360 and the annular non-magnetic layer 2365 can be deposited by an angular deposition process 2370 to improve deposition in the annular openings, as illustrated in FIG. 23C. The portions of the annular tunnel insulator layer 2355, the annular free magnetic layer 2360 and the annular non-magnetic layer 2365 at the bottom of the array of annular openings 2350 and on top of the planar non-magnetic insular layer 2345 can be removed by one or more selective etching, milling or the like processes 2375, as illustrated in FIG. 23D. Alternatively, the portions of the annular tunnel insulator layer, the annular free magnetic layer and the annular non-magnetic layer at the bottom of the array of annular openings and on top of the planar non-magnetic insular layers can be removed by successive etching, milling or the like processes before the subsequent layer is deposited. At 2255, non-magnetic regions can be formed in the annular free magnetic layer to separate the annular free magnetic layer into a plurality of portions aligned with the one or more planar reference magnetic layers. In one implementation, the non-magnetic regions 2380in the annular free magnetic layer 2360 can be formed by forming metal diffusion layers 2385 between the adjacent planar non-magnetic insulator layers 2315, 2340. Metal from the metal diffusion layer 2385 can diffuse into the annular free magnetic layer 2360 during one or more fabrication processes. The diffused metal in the annular free magnetic layer 2360 can form the non-magnetic regions 2380 in the annular free magnetic layer 2360 such that the resulting portions of the annular free magnetic layer 2360 are aligned with the planar reference magnetic layers 2320, 2325, 2330. In another implementation, the metal may be implanted into the annular free magnetic layer between adjacent planar non-magnetic insulator layers to form the non-magnetic regions in the annular free magnetic layer.

At 2260, annular conductive cores can be formed inside the annular non-magnetic layers in the array of annular openings. Th annular conductive cores in the array of annular openings can be coupled to a corresponding select transistor. In one implementation, an annular conductive core layer 2390 can be deposited on the surface of the annular magnetic layer 2345 inside and outside of the array of annular openings 2350, as illustrated in FIG. 23E. The annular conductive core can include one or more layers of MgO, SiOx, AlOx. are alloys thereof. Excess material of the annular conductive core layer 2390 can be removed by Chemical Mechanical Polishing (CMP) or other similar process to form annular conductive cores 2390 in the array of annular openings 2350, as illustrated in FIG. 23F.

At 2265, portions of one or more planar non-magnetic insulator layers and one or more planar reference magnetic layers can be removed in a periphery region to expose each planar reference magnetic layer. The periphery region can be outside the array of annular openings. In one implementation, a series of one or more etching, milling or the like processes can be used to step down through the planar non-magnetic insulator layers and the planar reference magnetic layers. At 2270, a bit line can be formed on each planar reference magnetic layer. In one implementation, a conductive layer can be deposited. A bit line pattern mask can be formed on the conductive layer and a selective etching process can be performed to remove the portions of the conductive layer exposed by the bit line pattern mask to form the plurality of bit lines on corresponding ones of the planar reference magnetic layers. The bit lines can be disposed as a plurality of substantially parallel traces in a first direction (e.g., rows) on respective planar reference magnetic layers, as illustrated in FIG. 13.

At 2275, one or more bit line vias can optionally be formed. The one or more bit line vias can be coupled to respective bit lines, as illustrated in FIGS. 18A and 18B. There are numerous conductive materials that can be utilized for the bit line vias, and there are numerous deposition, masking, and etching process that can be utilized for forming the plurality of bit line vias. The specific materials and processes are not germane to an understanding of aspects of the present technology and therefore will not be described in further detail.

At 2280, one or more global bit lines can be formed. The one or more global bit lines can be coupled to corresponding bit lines or bit line vias, as illustrated in FIGS. 7, 18A and 18B. In one implementation, two or more bit lines arranged in respective columns can be coupled together by a corresponding global bit line. There are numerous conductive materials that can be utilized for the global bit lines, and there are numerous deposition, masking, and etching process that can be utilized for forming the plurality of global bit lines. The specific materials and processes are not germane to an understanding of aspects of the present technology and therefore will not be described in further detail.

The foregoing descriptions of specific embodiments of the present technology have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the present technology and its practical application, to thereby enable others skilled in the art to best utilize the present technology and various embodiments with various modifications as are suited to the particular use contemplated. It is intended that the scope of the invention be defined by the claims appended hereto and their equivalents.

What is claimed is:

1. A Magnetic Tunnel Junction (MTJ) comprising:
an annular structure including an annular non-magnetic layer disposed about an annular conductive layer, an annular free magnetic layer disposed about the annular non-magnetic layer, and an annular tunnel insulator disposed about the annular free magnetic layer; and
a planar reference magnetic layer disposed about the annular structure and separated from the free magnetic layer by the annular tunnel barrier layer, wherein;
a magnetic field of the planar reference magnetic layer has a fixed polarization substantially parallel to a major planar orientation of the planar reference magnetic layer; and
a magnetic field of the annular free magnetic layer has a polarization substantially parallel to the major planar orientation of the planar reference magnetic layer and selectively switchable between being substantially parallel and substantially antiparallel to the magnetic field of the planar reference magnetic layer.

2. The MTJ of claim 1, wherein the annular structure comprises a conical structure including a conical non-magnetic layer disposed about a conical portion of the conductive layer, a conical free magnetic layer disposed about the conical non-magnetic layer, and a conical tunnel barrier layer disposed about the conical free magnetic layer.

3. The MTJ of claim 2, wherein the conical structure has a taper of approximately 10-45 degrees from a first side of the planar reference magnetic layer to a second side of the planar reference magnetic layer.

4. The MTJ of claim 1, further comprising:
a first set of one or more additional layers disposed about the annular structure and on a first side of the planar reference magnetic layer; and
a second set of one or more additional layers disposed about the annular structure and on a second side of the planar reference magnetic layer.

5. The MTJ of claim 1, wherein:
the annular free magnetic layer includes a Cobalt-Iron-Boron (Co—Fe—B) alloy;
the conductive annular layer includes one or more of Copper (Cu), copper alloy, Aluminum (Al), aluminum alloy, Ruthenium (Ru) or ruthenium alloy;
the annular tunnel insulator includes a Ruthenium (Ru) alloy; and
the planar reference magnetic layer includes a Cobalt-Iron-Boron (Co—Fe—B) alloy.

6. The MTJ of claim 1, wherein the magnetic field of the annular free magnetic layer is configured to switch to being substantially parallel to the magnetic field of the planar reference magnetic layer in response to a current flow in a first direction through the conductive annular layer and to switch to being substantially anti-parallel to the magnetic field of the planar reference magnetic layer in response to a current flow in a second direction through the conductive annular layer.

7. A device comprising:
a first plurality of annular structures, each annular structure including an annular non-magnetic layer disposed about an annular conductive layer, an annular free magnetic layer disposed about the annular non-magnetic layer, and an annular tunnel insulator disposed about the annular free magnetic layer; and
a first planar reference magnetic layer disposed about the first plurality of annular structures and separated from the free magnetic layers by the annular tunnel barrier layers, wherein;
a magnetic field of the first planar reference magnetic layer has a fixed polarization substantially parallel to a major planar orientation of the first planar reference magnetic layer; and
a magnetic field of the annular free magnetic layer of each annular structure has a polarization substantially parallel to the major planar orientation of the first planar reference magnetic layer and selectively switchable between being substantially parallel and substantially antiparallel to the magnetic field of the first planar reference magnetic layer.

8. The device of claim 7, further comprising:
a first non-magnetic insulator layer disposed about the first plurality of annular structures and on a first side of the first planar reference magnetic layer;
a second non-magnetic insulator layer disposed about the first plurality of annular structures and on a second side of the first planar reference magnetic layer;
a second plurality of annular structures axially aligned with respective ones the first plurality of annular structures;
a second planar reference magnetic layer disposed about the second plurality of annular structures and separated from the free magnetic layer of the second plurality of annular structures by the annular tunnel barrier layers of the second plurality of annular structures;
a third non-magnetic insulator layer disposed about the second plurality of annular structures and between the second non-magnetic insulator layer and a first side of the second planar reference magnetic layer; and
a fourth non-magnetic insulator layer disposed about the second plurality of annular structures and on a second side of the second planar reference magnetic layer.

9. The device of claim 8, further comprising:
a non-magnetic metal layer disposed between the second non-magnetic insulator layer and the third non-magnetic insulator layer and between the first plurality of annular structures and the second plurality of annular structures.

10. The device of claim 8, further comprising:
an additional non-magnetic insulator layer disposed between the second non-magnetic insulator layer and the third non-magnetic insulator layer; and
a non-magnetic metal plug disposed between respective ones of the annular conductive layer of the first plurality of annular structures and the annular conductive layer of the second plurality of annular structures.

11. The device of claim 7, further comprising:
the first planar reference magnetic layer aligned with a first portion of the annular free magnetic layer of the first plurality of annular structures;
a first non-magnetic insulator layer disposed about the first plurality of annular structures and on a first side of the first planar reference magnetic layer;
a second non-magnetic insulator layer disposed about the first plurality of annular structures and on a second side of the first planar reference magnetic layers;
a second planar reference magnetic layer disposed about the first plurality of annular structures and separated from the free magnetic layers of the first plurality of annular structures by the annular tunnel barrier layers of the first plurality of annular structures, and the second planar reference magnetic layer aligned with a second portion of the annular free magnetic layer of the first plurality of annular structures;
a third non-magnetic insulator layer disposed about the first plurality of annular structures and between the second non-magnetic insulator layer and a first side of the second planar reference magnetic layer; and
a fourth non-magnetic insulator layer disposed about the first plurality of annular structures and on a second side of the second planar reference magnetic layer.

12. The device of claim 11, further comprising:
a non-magnetic metal layer disposed between the second non-magnetic insulator layer and the third non-magnetic insulator layer.

13. The device of claim 7, wherein each annular structure has a taper of approximately 10-45 degrees from a first side of the first planar reference magnetic layer to a second side of the first planar reference magnetic layer.

14. The device of claim 7, wherein the magnetic field of the annular free magnetic layer of each annular structure is configured to switch to being substantially parallel to the magnetic field of the first planar reference magnetic layer in response to a current flow in a first direction through the conductive annular layer and to switch to being substantially anti-parallel to the magnetic field of the first planar reference magnetic layer in response to a current flow in a second direction through the conductive annular layer.

15. The device of claim 7, wherein each annular structure and the portion of the first planar reference magnetic layer proximately the respective annular structure comprises a Magnetic Tunnel Junction (MTJ) cell.

16. A memory device comprising:
an array of Magnetic Tunnel Junction (MTJ) cells including;
a plurality of annular structures arranged in columns and rows, each annular structure including an annular non-magnetic layer disposed about an annular conductive layer, an annular free magnetic layer disposed about the annular non-magnetic layer, and an annular tunnel insulator disposed about the annular free magnetic layer; and
a planar reference magnetic layer disposed about the plurality of annular structures and separated from the free magnetic layers by the annular tunnel barrier layers, wherein;
a magnetic field of the planar reference magnetic layer has a fixed polarization substantially parallel to a major planar orientation of the planar reference magnetic layer; and
a magnetic field of the annular free magnetic layer of each annular structure has a polarization substantially parallel to the major planar orientation of the planar reference magnetic layer and selectively switchable between being substantially parallel and substantially antiparallel to the magnetic field of the planar reference magnetic layer;
a bit line coupled to the planar reference magnetic layer; and
a plurality of select transistors, each select transistor coupled to the annular conductive layer of a respective annular structure.

17. The memory device of claim 16, further comprising:
a plurality of word lines, each word line coupled to gates of a set of the plurality of select transistors arranged in a corresponding row of the plurality of annular structures; and
a plurality of source lines, each source line coupled to sources of a set of the plurality of select transistors arranged in a corresponding column of the plurality of annular structures.

18. The memory device of claim 16, further comprising:
a plurality of blocks of the array of MTJ cells arranged in columns and rows.

19. The memory device of claim 18, further comprising:
a plurality of global bit lines, each global bit line coupled to a set of bit lines in a corresponding column of the plurality of blocks of the array of MTJ cells.

20. The memory device of claim 16, wherein the plurality of bit lines are peripherally disposed about the array of MTJ cells.

21. The memory device of claim 16, wherein the magnetic field of the annular free magnetic layer of each annular structure is configured to switch to being substantially parallel to the magnetic field of the planar reference magnetic layer in response to a current flow in a first direction through the conductive annular layer and to switch to being substantially anti-parallel to the magnetic field of the planar reference magnetic layer in response to a current flow in a second direction through the conductive annular layer.

22. A method of manufacturing a Magnetic Tunnel Junction (MTJ) comprising:
forming a first planar non-magnetic insulator layer;
forming a planar reference magnetic layer on the first planar non-magnetic insulator layer, wherein a magnetic field of the planar reference magnetic layer has a fixed polarization substantially parallel to a major planar orientation of the planar reference magnetic layer;
forming a second planar non-magnetic insulator layer on the planar reference magnetic layer;
forming one or more annular openings through the second planar non-magnetic insulator layer, the planar reference magnetic layer and the first planar non-magnetic insulator layer;
forming an annular tunnel insulator on the walls of the one or more annular openings;
forming an annular free magnetic layer on the annular insulator inside the one or more annular openings, wherein a magnetic field of the annular free magnetic layer has a polarization substantially parallel to the major planar orientation of the planar reference magnetic layer and selectively switchable between being substantially parallel and substantially antiparallel to the magnetic field of the planar reference layer;
forming an annular non-magnetic layer on the annular free magnetic layer inside the one or more annular openings; and
forming an annular conductive core inside the annular non-magnetic layer in the one or more annular openings.

23. The method according to claim 22, wherein forming the one or more annular openings comprises milling a conical opening through the second planar non-magnetic insulator layer, the planar reference magnetic layer and the first planar non-magnetic insulator layer.

24. The method according to claim 22, wherein the one or more annular openings have a taper of approximate 10-45 degrees from a first side of the planar reference magnetic layer to a second side of the planar reference magnetic layer.
